(19) United States
(12) Patent Application Publication
(10) Pub. No.: US 2023/0271822 A1
(43) Pub. Date: Aug. 31, 2023

(54) MICRO-ELECTROMECHANICAL SYSTEM (MEMS) INCLUDING TANTALUM AS A STRUCTURAL MATERIAL

(71) Applicant: Carnegie Mellon University, Pittsburgh, PA (US)

(72) Inventors: Maarten P. de Boer, Barcelona (ES); Longchang Ni, Pittsburgh, PA (US); Ryan M. Pocratsky, Pittsburgh, PA (US)

(21) Appl. No.: 18/010,011

(22) PCT Filed: Jul. 1, 2021
(86) PCT No.: PCT/US2021/040196

§ 371 Date: Dec. 13, 2022

Related U.S. Application Data
(60) Provisional application No. 63/046,736, filed on Jul. 1, 2020.
(60) Provisional application No. 63/145,508, filed on Feb. 4, 2021.
(60) Provisional application No. 63/152,993, filed on Feb. 24, 2021.

(51) Int. Cl. B81B 3/00

(52) U.S. Cl. CPC B81B 3/0021; B81B 2201/0235; B81B 2203/0118; B81B 2203/0307; B81B 2207/115

(57) ABSTRACT

A micro-electromechanical system (MEMS) device includes a silicon substrate; and a Tantalum (Ta) layer comprising a first portion and a second portion, a first portion being suspended over the silicon substrate and configured to move relative to the silicon substrate, and the second portion of the structure being coupled to the silicon substrate and fixed in place relative to the silicon substrate. MEMS devices including accelerometers, gyroscopes, microphones, etc. can be fabricated in which Ta forms the structure material of the MEMS components on a chip. The Ta and integrated circuit (IC) can be fabricated together in a single package in which the MEMS structure is able to use the full area above the IC in the package.

### CLAIM OF PRIORITY

This application claims priority under 35 U.S.C. § 119(e) to U.S. Patent Application Ser. No. 63/046,736, filed on Jul. 1, 2020, to U.S. Patent Application Ser. No. 63/145,508, filed on Feb. 4, 2021, and to U.S. Patent Application Ser. No. 63/152,993, filed on Feb. 24, 2021, the entire contents of each of which are hereby incorporated by reference.

### GOVERNMENT SUPPORT CLAUSE

This invention was made with government support under grant number CMMI-1635332 awarded by US National Science Foundation (NSF). The government has certain rights in the invention.

### TECHNICAL FIELD

This disclosure relates generally to micro-electromechanical systems (MEMS). Specifically, this disclosure relates to MEMS including tantalum (Ta) metal as a structural material for one or more elements of the MEMS.

### BACKGROUND

MEMS include microscopic devices, particularly those with moving parts. MEMS generally include a central unit that processes data (an integrated circuit chip such as microprocessor) and several components that interact with the surroundings (such as microsensors). Silicon and metals can be used to create MEMS elements. Metals can exhibit very high degrees of reliability. Metals can be deposited by electroplating, evaporation, and sputtering processes.

### SUMMARY

This disclosure describes processing, modeling and characterization of nanocrystalline refractory metal tantalum (Ta) as a new structural material for MEMS thermal actuators (TAs). MEMS devices including accelerometers, gyroscopes, microphones, etc. can be fabricated in which Ta forms the structure material of the MEMS components on a chip. The Ta and integrated circuit (IC) can be fabricated together in a single package in which the MEMS structure is able to use the full area above the IC in the package.

The disclosure describes several example MEMS devices in which Ta is a structure material. While these examples are illustrative of several devices (such as thermal actuators), many other MEMS devices can be fabricated using Ta as the structural material using similar processes as described herein. For example, TA actuators made of Ta-based MEMS can be used in applications such as disk drives, micro- and nanopositioners, microgrippers, scanning probes, optical attenuators, micromirrors, gyroscopes, linear and rotary microengines, switches, and nanomechanical property test platforms. The Ta MEMS described herein generally include α-phase Ta, which is etched into 2.5 micrometer (μm) thick sputter-deposited films of 1 μm width while maintaining a vertical or nearly vertical sidewall profile to ensure in-plane movement of TA legs. The thickness of 2.5 μm is 25 times thicker than the thickest reactive ion etched α-Ta reported. The structures include a V-shaped thermal actuator that is fabricated and tested in air. Both conventional actuation via Joule heating and passive self-actuation tests are performed and concur with prediction models.

This disclosure describes processes for fabrication of MEMS devices including Ta as structure material. A process for application of Ta to the silicon substrate is performed in which residual stress sensitivities in the Ta structure to sputter parameters and to hydrogen incorporation are investigated and controlled. The stress can be controlled to near zero stress. Low-stress application enables Ta to be applied to the silicon substrate (e.g., on or over an IC) without reducing the effectiveness of the structure. This disclosure describes a process for anisotropic etching for generation of Ta structures. The etching produces Ta structures in which the sidewalls are approximately orthogonal to the substrate. There is little or no lateral etching in the Ta structure. This enables structures to be fabricated directly on an IC in which the structure shape is precisely controlled. For example, structures can be controlled to widths of 1 μm as needed. The etching process includes use of or Aluminum Nitride (AlN) and Copper (Cu) as a sacrificial material, as subsequently described.

The systems and processes described in this document enable one or more of the following advantages. While parallel plate or comb-driven electrostatic actuators require relatively high driving voltages (≥30 V) and generate forces rarely exceeding 10 μN, thermal actuators (TAs) use lower operation voltage (5-10 V) yet provide higher output force on the order of millinewtons mN. Compared with other common actuation mechanisms involving piezoelectric materials, magnetic materials or shape memory alloys, the use of which can be prevented by processing constraints, TAs are generally compatible with standard MEMS manufacturing methods, easily scalable in size and have a more compact structure.

For MEMS TAs, polycrystalline silicon (polysilicon, PS) has been the dominant structural material. However, PS TA legs typically operate at temperatures 300-500° C. higher than the substrate to generate useable displacement and force output because PS's coefficient of thermal expansion (CTE, αₛᵢ≈2.7 με/° C. ¹⁵) is the same as the silicon substrate. This causes relatively large power consumption, which is a well-known drawback. In addition, structural PS is typically annealed at 1000° C. to control the residual stress, a temperature that is incompatible with many processes and materials, and prohibits post-processing on complementary metal-oxide-semiconductor (CMOS) foundry parts. The 5-10 V operation further makes them at best indirectly compatible with CMOS, which typically operates at ≲1 V.

To overcome these drawbacks, the Ta structural materials for MEMS described herein have high CTE, can be deposited with low intrinsic residual stress and stress gradient, can operate at lesser power and lower voltage, and can be processed at lower temperatures in comparison to PS-based MEMS TAs. For example, nano-crystalline Ta films have comparable coefficient of thermal expansion (CTE) and Young's modulus to bulk Ta, but have approximately ten times greater yield strength than bulk Ta. The mechanical properties and grain size of nano-crystalline Ta remain stable after annealing at temperatures as high as 1000° C. Ta has a high melting temperature (Tₘ=3017° C.) and a low resistivity (ρ=20 μΩ·cm), and it can withstand annealing processes performed during IC fabrication. Compared to thermal actuators (TAs) made from the dominant MEMS material, PS (Tₘ=1414° C., ρ=2000 μΩ·cm), Ta TAs can require less than half the power input for the same force and displacement. In addition the temperature change for Ta structures can be half polycrystalline silicon typically used as MEMS materials. Ta MEMS can operate at up to 16 times lower voltage than Si MEMS, making Ta MEMS compatible with CMOS voltage levels and power requirements. Additionally, Tantalum is useful for TAs because Tantalum has a large CTE (α_{Ta}=6.3 με/° C.) compared to Mo (α_{Mo}=4.8 με/° C.) or W (α_{w}=4.5 με/° C.) ²⁵. In principle, isothermal self-actuation is enabled in Ta-based TAs due to the CTE mismatch between Ta and the Si substrate, which can be useful for temperature sensing. Generally, as the temperature changes, the TA displacement changes. The displacement change has a one-to-one correspondence with the temperature change. This can be sensed electrically (through capacitance change, or through actually making physical contact) or optically (through either direct visualization or by laser beam reflections).

The sacrificial layers described herein for Ta MEMS enable fabrication without using an organic sacrificial layer that is removed by an oxygen ash. Typically, because ashing is not applicable to metals that are susceptible to oxidation, inorganic sacrificial silicon dioxide is used, but its removal commonly involves acids, exposure to which can be detrimental to metals. This disclosure describes structural Ta MEMS fabrication using AlN and Cu as alternative sacrificial materials in which release etching of structural Ta by each of AZ 400K developer and FeCl3 solution, respectively, is hydrogen free. Isotropic release etching is observed for Cu at room temperature and for AlN above 60° C. but generally below 90° C. In comparison with 1200 megapascals (MPa) for a conventional, hydrogen-based release process, the uniaxial stress change after structure release is about 80 MPa compressive with Cu and is unchanged after AlN sacrificial etch.

While TAs are shown as a proof-of-concept example, the Ta layer can be shaped using the processes described herein to form any MEMs device, including accelerometers, gyroscopes, cantilevers, and so forth. The processes described herein for performing etching of the Ta layer and for reducing or eliminating residual stresses of the Ta layer enable the Ta layer to form a wide variety of microstructures on the silicon substrate. Additionally, as described herein, the low-temperature release process for the Ta layer during etching of Cu or AlN sacrificial layers enables the Ta microstructures to be formed directly on fabricated CMOS structures, as the CMOS structures can tolerate the mild temperatures (>90° C.) of the release processes described herein for AlN or Cu sacrificial layers.

The one or more advantages previously described can be enabled by one or more embodiments.

In a general aspect, a micro-electromechanical system (MEMS) device includes a silicon substrate; and a Tantalum layer comprising a first portion and a second portion, a first portion being suspended over the silicon substrate and configured to move relative to the silicon substrate, and the second portion of the structure being coupled to the silicon substrate and fixed in place relative to the silicon substrate.

In some implementations, the silicon substrate forms a portion of an integrated circuit (IC), wherein the Tantalum layer and the IC are included in a package.

In some implementations, the MEMS device includes a sacrificial layer between the silicon substrate and the Tantalum layer, wherein a first portion of the sacrificial layer is etched away to release the first portion from the silicon substrate, and wherein a second portion of the sacrificial layer remains and couples the silicon substrate to the Tantalum layer. In some implementations, the sacrificial layer comprises Aluminum Nitride (AlN), Copper (Cu), or Silicon Oxide (SiO₂).

In some implementations, the first portion comprises etched Tantalum, and wherein a sidewall profile of the etched Tantalum comprises approximately zero lateral etch or an etch angle between 85-90° C.

In some implementations, the first portion includes a plurality of legs extending from a first side of the silicon substrate or a second side of the silicon substrate to connect at a shuttle, the plurality of legs being coupled to the silicon substrate at the first and second sides, wherein the plurality of legs support in-plane movement of the shuttle. In some implementations, at least one leg of the plurality of legs are each between 1-2.5 micrometers (μms) thick, and wherein each of the plurality of legs have an approximately equal thickness. In some implementations, each of the plurality of legs have an approximately equal width. In some implementations, at least one leg of the plurality of legs has a width of approximately 1 μm and spaced about 2-4 μm.

In some implementations, the first portion has a residual stress of less than 50 megaPascals (MPa), the residual stress being based on a buffered hydrofluoric acid (BHF) release of the first portion from a sacrificial layer.

In some implementations, the first portion comprises a central portion suspended over the silicon substrate and configured to move up to 5 μm responsive to an electrical or thermal input.

In some implementations, the Tantalum layer is formed directly on a CMOS circuit, and wherein an isotropic release etching of the sacrificial layer comprising AlN is between 60° C.-90° C.

In some implementations, the Tantalum layer comprises grain sizes of approximately 160 nm.

In some implementations, the Tantalum layer is at least 2.5 micrometers (μm) thick.

In some implementations, the Tantalum layer comprises α-Tantalum.

In some implementations, the first portion of the Ta layer forms a portion of a thermal actuator (TA). In some implementations, the first portion is configured to deflect at least 1.5 um in response to receiving a current of less than 15 mA based on a length, a width, or a thickness of the first portion of the Ta layer. In some implementations, the first portion is configured to deflect at approximately 1 μm in response to receiving a temperature of about 100° C. based on a length, a width, or a thickness of the first portion of the Ta layer.

In some implementations, the MEMS device includes a Chromium seed layer configured to nucleate the Tantalum layer during sputtering.

In some implementations, the first portion of the Ta layer forms a cantilever.

In some implementations, the first portion of the Ta layer is part of an accelerometer.

In some implementations, the MEMS device includes a coating such as atomic layer deposition of Al₂O₃ configured to provide oxidation resistance.

In some implementations, a micro-electromechanical system (MEMS) actuator device includes a silicon substrate; and a α-Tantalum film forming a plurality of leg pairs, the leg pairs extending from a first side of the α-Tantalum film or a second side of the Tantalum film to a shuttle suspended above the silicon substrate, the first and second sides being affixed to the silicon substrate by at least one underlayer, the plurality of leg pairs being configured for in-plane deflection relative to the silicon substrate.

In some implementations, each leg of the plurality of leg pairs is at least 150 μm long, 2.5 μm thick, and 1 μm wide.

In some implementations, each leg of the plurality of leg pairs comprises a sidewall profile having approximately no lateral etch.

In some implementations, the underlayer comprises a thermal SiO₂ sacrificial layer, a Chromium hard mask, or both.

In some implementations, each leg of the plurality of leg pairs is configured for a 5 μm offset of the central shuttle in a deactivated position and up to a 10 μm offset of the central shuttle in an activated position.

In a general aspect, a micro-electromechanical system (MEMS) device, includes an oxide substrate; a Tantalum structure coupled to a first portion of the oxide substrate, a portion of the Tantalum structure extending over a second portion of the oxide and configured to move relative to the oxide substrate; and a complementary metal-oxide-semiconductor (CMOS) structure formed in the oxide substrate, the CMOS structure being electrically coupled to the Ta structure.

In some implementations, the Tantalum structure forms a comb.

In some implementations, the Tantalum structure forms one of a cantilever, a fixed-fixed beam, or other structure fixed on two ends.

The details of one or more implementations are set forth in the accompanying drawings and the description below. Other features and advantages will be apparent from the description and drawings, and from the claims.

### BRIEF DESCRIPTION OF DRAWINGS

FIG. 1A illustrates an example of a MEMS device.

FIG. 1B illustrates an example of a MEMS device.

FIG. 1C illustrates a graph showing displacements and temperatures.

FIG. 1D an example process for fabrication of a MEMS device.

FIG. 2A illustrates an example of a MEMS device.

FIG. 2B illustrates example graphs.

FIG. 3 illustrates an example graph.

FIG. 4 illustrates an example X-ray diffraction (XRD) diagram.

FIG. 5A illustrates an example graph.

FIG. 5B illustrates example images of materials.

FIG. 6 illustrates example image of etched material.

FIG. 7 an example process for fabrication of a MEMS device.

FIG. 8 illustrates an example graph.

FIG. 9 illustrates an example of a MEMS device.

FIG. 10 illustrates example graphs.

FIG. 11 illustrates an example process for fabrication of a MEMS device.

FIG. 12 illustrates an example of Ta structures.

FIG. 13 illustrates an example graph.

FIG. 14 illustrates an example diagram.

FIG. 15 illustrates an example diagram.

FIG. 16 illustrates an example graph.

FIG. 17 illustrates an example graph and example interferograms.

FIG. 18 illustrates an example process for fabrication of a MEMS device.

FIG. 19 illustrates an example diagram and an example image of a portion of a MEMS device.

FIG. 20 illustrates an example images of portions of a MEMS device.

FIG. 21 illustrates an example images of portions of a MEMS device and a graph.

FIG. 22 illustrates an example graph.

FIGS. 23-28 each illustrates example images of etched materials.

FIG. 29 is a flow diagram illustrating an example process for fabrication of a MEMS device.

Like reference symbols in the various drawings indicate like elements.

### DETAILED DESCRIPTION

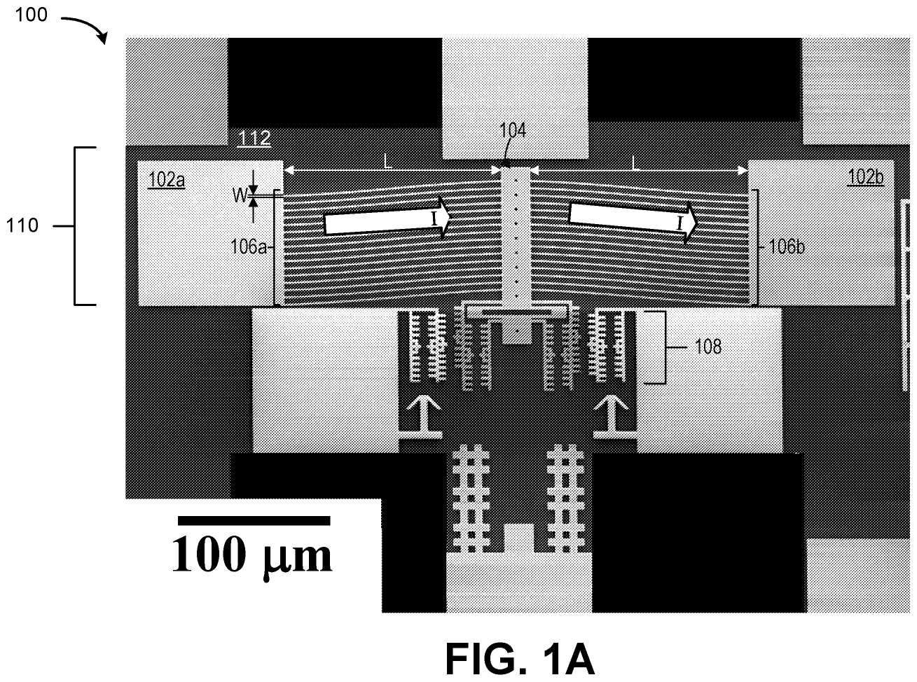

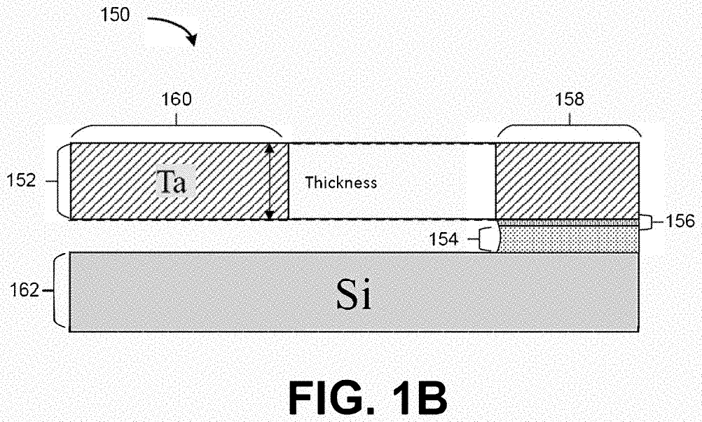

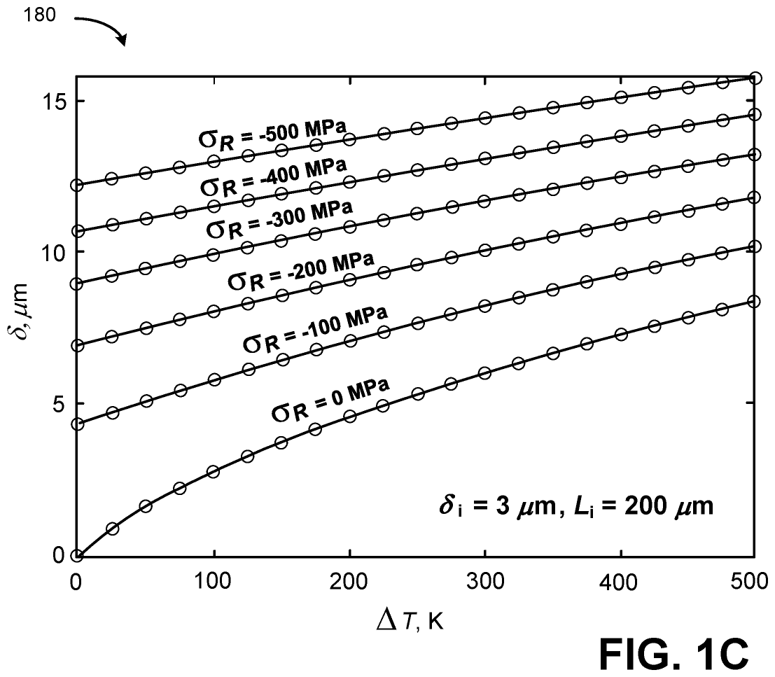

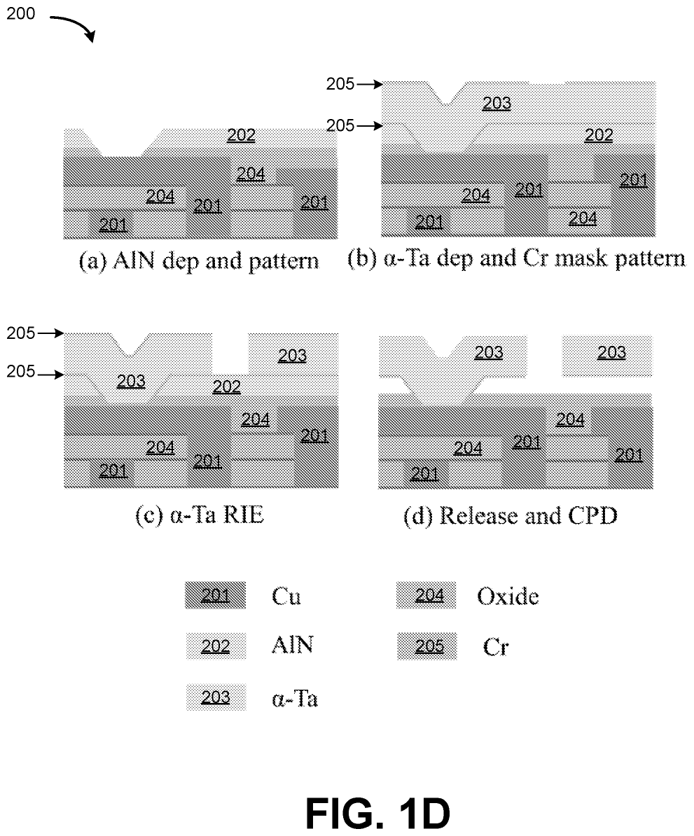

FIG. 1A shows am top view of an example MEMS device 100 including a V-shaped thermal actuator (TA) with a Tantalum (Ta) based MEMS structure 110. The MEMS structure 110 includes a plurality of legs 106a and legs 106b that together form a plurality of leg pairs. The legs 106a-b are coupled to a substrate (e.g., a silicon substrate) 112 at a first portion 102a of a Tantalum layer and a second portion 102b of the Tantalum layer. The legs are configured to move a central shuttle 104 in response to input actuation signals (e.g., changes in ambient temperature or by Joule heating, etc.). A Vernier scale 108 is included on the MEMS device 100 to measure a change in position of the shuttle and thus actuation of the TA. The MEMS device 100 is configured for in-plane deflection of the shuttle 104 of a distance up to 5-10 μm once the sacrificial layer has been removed.

While TAs are shown as a proof-of-concept example, the Ta layer (e.g., layer 152 of FIG. 1B) can be shaped using the processes described herein to form any MEMs device, including accelerometers, gyroscopes, cantilevers, and so forth. The processes described herein for performing etching of the Ta layer and for reducing or eliminating residual stresses of the Ta layer enable the Ta layer to form a wide variety of microstructures on the silicon substrate. Additionally, as described herein, the low-temperature release process for the Ta layer during etching of Cu or AlN sacrificial layers enables the Ta microstructures to be formed directly on fabricated CMOS structures, as the CMOS structures can tolerate the mild temperatures (>90° C.) of the release processes described herein for AlN or Cu sacrificial layers.

The legs 106a-b have a projected length marked L and a width marked W. The thickness of the legs 106a-b is determined based on the thickness of the Ta layer that is included in the MEMS device 100. The thickness can be, for example, about 1 μm to 2.5 μm. Other thickness can be achieved, as subsequently described, depending on the application or particular MEMS device. In some implementations, thicker Ta layers (e.g., >2.5 μm) improves sensor performance for accelerometers, and gyroscopes. Thicker Ta layers (e.g., >2.5 μm) can perform better than thinner Ta layers for increasing force in thermal actuators. A thicker Ta layer (e.g., >2.5 μm) makes fabrication easier for achieving flat structures such as comb fingers, which are used in accelerometers and gyroscopes. This is because beam moment of inertia scales with thickness to the third power. For a same stress gradient (e.g., residual stress variation with thickness), a response curvature will decrease. Thicknesses of 10-25 μm are achievable. The legs can have a spacing of less than 5 μm.

Though a particular geometry is described herein for device 100, this geometry is an example of one particular MEMS structure formed from Ta. A wide variety of geometries for various sensors can be achieved using the processes for forming device 100 as described herein. For example, the Ta can form combs, cantilevers, beams, forks, or any similar shape.

FIG. 1B shows a side-view of a MEMS device 150, such as a portion of device 100 of FIG. 1A. The MEMS device 150 generally includes a silicon substrate layer 162 (e.g., similar to substrate 112 of FIG. 1A) and a Tantalum layer 152 forming a MEMS structure (e.g., structure 110) on top of the substrate 162. A first portion of the structure 160, such as the legs 106a-b and the shuttle 104 of FIG. 1A, is suspended over the silicon substrate 162 and is configured to move relative to the silicon substrate (e.g., in response to actuation). A second portion 158 of the structure (e.g., structure 110, which can include a base structure 102a and a base structure 102b of FIG. 1A, are coupled to the silicon substrate 162 typically through an underlayer. The underlayer can include a hard Chromium layer 156 and a portion of a sacrificial layer 154 (e.g., Cu, AlN, etc.) that is not etched away, as subsequently described. In some implementations, the sacrificial layer 154 and the Cr underlayer 156 undercut the Ta layer 152 several microns, though this is not necessarily always the case.

The portion 158 (e.g., including base structures 102a-b) are fixed in place relative to the silicon substrate 162 and anchor the moveable portion 160 of the structure 110, including legs 106a-b and shuttle 104, to the substrate 162. Generally, the silicon substrate 162 forms a portion of an integrated circuit (IC). As subsequently described, the Tantalum layer 152 and the integrated circuit are included in a single IC package that is fabricated in a single process.

The sacrificial layer 154 is between the silicon substrate 162 and the Tantalum layer 152. Generally, a first portion of the sacrificial layer is etched away to release the moveable portion 160 of the Ta structure from the silicon substrate 162. A second portion of the sacrificial layer 154 remains and couples the silicon substrate 162 to the Tantalum layer 152 for the fixed portion 158 of the Ta layer. As subsequently described, the sacrificial layer includes one of Aluminum Nitride (AlN), Copper (Cu), or Silicon Oxide (SiO₂), though other metals may be applicable.

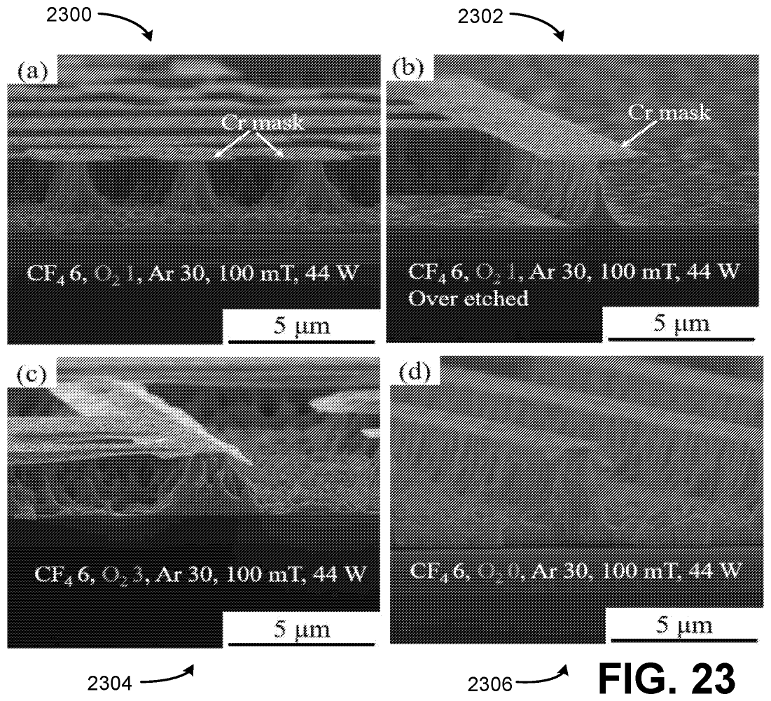

As subsequently described, the moveable portion 160 of the structure 110 includes etched Tantalum. A sidewall profile of the etched Tantalum generally has approximately zero lateral etch after the etching processes, subsequently described in detail in relation to FIGS. 23-28, is performed. The etch angle (or sidewall provide angle) is generally sidewall profile angle greater than 80°, where 90° is vertical. Specifically, the etch angle achieved with Ta can be about 87°, or at least greater than 85°.

The MEMS Ta structure can greatly vary in geometry depending on the particular application. For the MEMS structure 110, which forms a thermal actuator, the plurality of legs 106a-b can are each between 1-2.5 micrometers (μms) thick. Generally, because they are formed from the Ta layer 152, the plurality of legs have a same thickness that is equal or nearly equal to the thickness of the Ta layer 152. In some implementations, each of the plurality of legs 106a-b have an approximately equal width W, such as approximately 1 μm. However, the width of any given leg or other portion of the Ta structure 110 can be adjusted based on the etch mask applied to the Ta layer during fabrication. In some implementations, at least one leg of the plurality of legs 106a-b has a length L of about 10-20 μm. Generally, each of the legs 106a-b has a same length L to stabilize the shuttle 104.

As subsequently described, a residual stress for the Ta layer 152 can be reduced to near zero. In some implementations, the moveable portion 160 of the structure 110 has a residual stress of less than 50 megaPascals (MPa). The residual stress can be based on a buffered hydrofluoric acid (BHF) release of the moveable portion 160 of the structure 110 from the sacrificial layer 154.

The Ta layer 152 is generally deposited onto the sacrificial layer by a sputtering process. A stress target of 0 MPa is preferred. A dedicated sputter deposition system can control what the stress is during application of the Ta layer 152 to achieve low deposition stress.

Generally, the processes described herein reduce stress that occurs in response to subsequent processing of device (e.g., etching and release of the moveable portion 160 of the MEMS device). Generally, if a stress is introduced during this subsequent processing, then it can be controlled and made stable. To reduce residual stress, alpha-Tantalum (α-Ta) is used for the Ta layer 152, as subsequently described in further detail. The α-Ta is the equilibrium phase, but only forms if deposited on the appropriate corresponding seed layer or underlayer. The residual stress is much less dependent on subsequent thermal cycling than is beta-Tantalum (β-Ta).

The release process can determine how much residual stress is introduced to the structure 110. In an example, if SiOx (x≈2) is used as a sacrificial layer and do the release in HF, and perform a degassing process, a stress change from the as-deposited Ta layer 152 is about −50 MPa. In another example, if the sacrificial layer includes Cu, the stress change from the as-deposited Ta layer 152 is about −80 MPa. In another example, if the sacrificial layer includes AlN as the sacrificial layer, the stress change from the as-deposited Ta layer 152 is about 0 MPa (e.g., is not detectable).

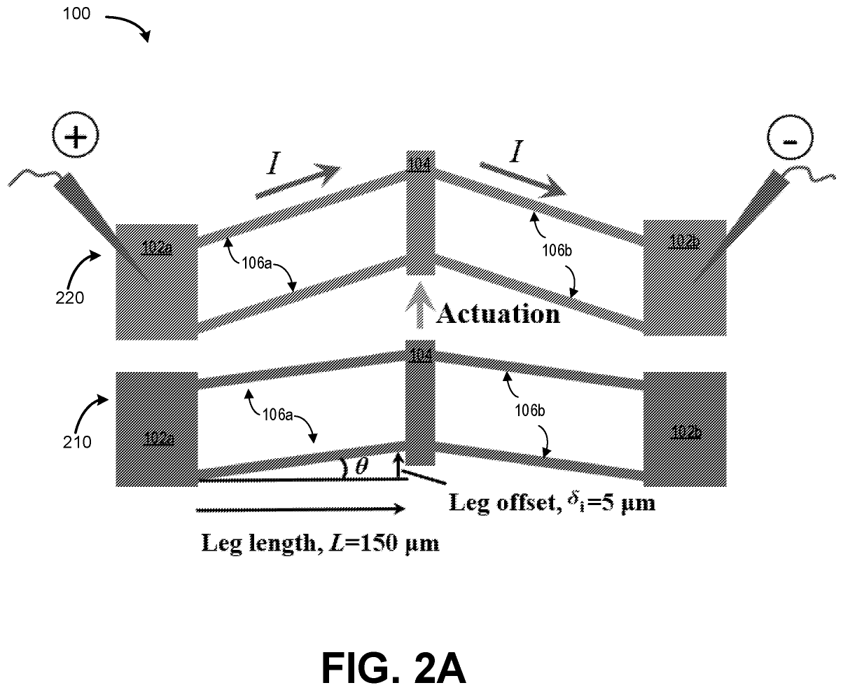

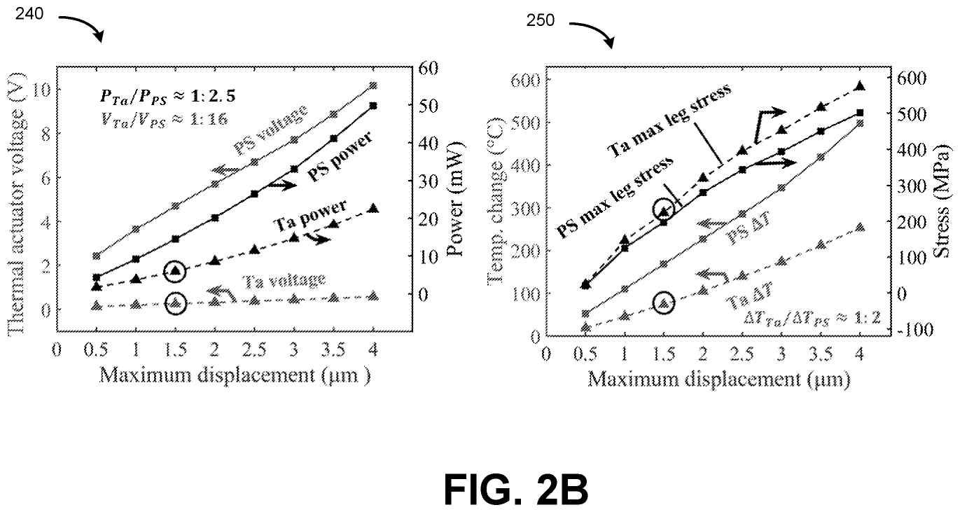

The amount of movement or actuation for a MEMS device (such as device 100 or 152 of FIGS. 1A-1B) can vary greatly depending on the geometry of the device. For thermal actuators, this depends strongly on geometry. Residual stress causes an initial displacement, seen in FIG. 2 and shown in greater detail in graph 180 of FIG. 1C. For structures that are only supported on one side, such as comb drives, accelerometers, gyroscopes, etc., this residual stress is relieved. The stress gradient (which gives rise to out-of-plane curvature is controlled, as subsequently described.

As shown in graph 180 of FIG. 1C, ΔT arises either from raising a temperature of the structure 110, or from passing current through the legs 106a-b (which gives rise to an effective temperature). Lᵢ is an initial leg length and Δᵢ is an initial leg offset (e.g., θ in FIG. 2). Generally, actuation or offset values for accelerometers and gyroscopes depend on lateral (in-plane) capacitance, which is high because of the thick Ta layer. The graph 180 shows the relationships between actuation movement (e.g., delta δ) of part of the movable portion of the structure 160 (e.g., shuttle 104) and various residual stresses for that movable portion 160 given different geometrical properties of the structure.

In an embodiment, the shuttle 104 is suspended over the silicon substrate 112 and configured to move up to 5 μm responsive to an electrical or thermal input. In an embodiment, each of the plurality of legs 106a-b have an approximately equal width. In an embodiment, at least one leg of the plurality of legs has a width of about 1 μm and a length L of about 150 μm. In an embodiment, the moveable portion 160 of the structure 110 has a residual stress of less than 50 megaPascals (MPa), the residual stress being based on a buffered hydrofluoric acid (BHF) release of the first portion of the structure from a sacrificial layer.

In an implementation, the Tantalum layer 152 comprises annealed Tantalum. The annealed Tantalum is formed from an annealing process of at least 500° C., in situations in which a hydrogen degas is performed. The annealed Tantalum has a yield strength of at least 2.5 Gigapascal (GPa). This enables fabrication of a wide variety of devices, such as accelerometers, gyroscopes, microphones, mass sensors, pressure sensors and RF passive devices on top of ICs, as enabled by the anisotropic etching of thick Ta (e.g., >=2.5 μm). The anisotropic etching of thick Ta enables lateral (in-plane) sensing. For example, accelerometers and gyros have movable portions 160 that move in-plane. In some implementations, fabrication temperature is kept at a limit of 90° C., such as during AlN release.

In embodiments, the Tantalum layer 152 comprises grain sizes of about 160 nm. In embodiments, the Tantalum layer 152 is nominally 2.5 micrometers (μm) thick. However, thicker layering of Ta is possible using the etching process subsequently described. Generally, the Tantalum layer 152 comprises α-Tantalum.

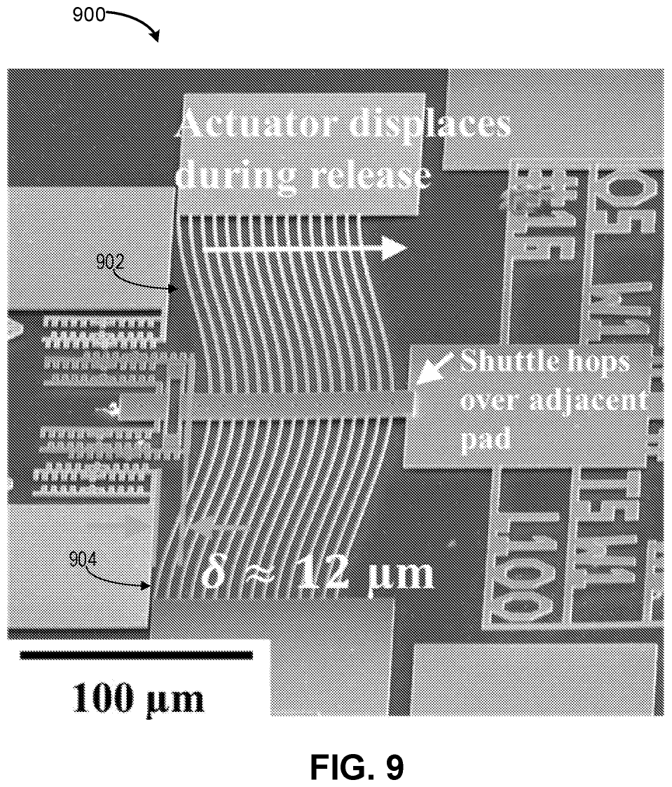

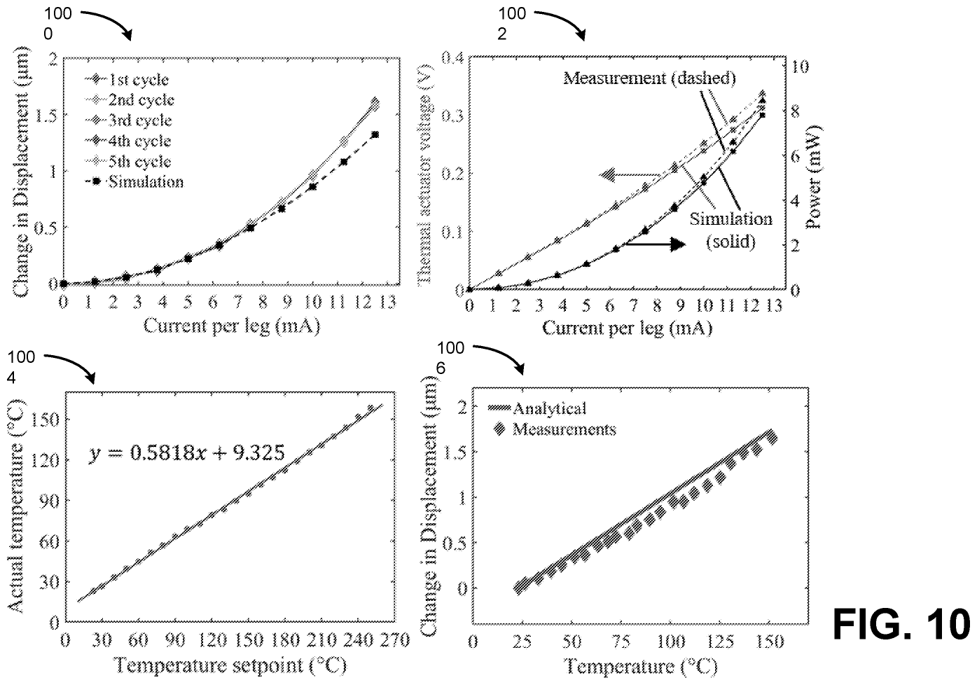

In an embodiment, the shuttle 104 of the device 100 is configured to deflect at least 1.5 um in response to receiving a current of less than 15 mA along arrows marked I in FIG. 1A. The shuttle 104 includes release holes. In an embodiment, the shuttle 104 of the device 100 is configured to deflect at approximately 1 μm in response to receiving a temperature of about 100° C. However, other values are possible, and subsequently described (e.g., in relation to FIGS. 9-10).

As seen in FIG. 1B, the device 150 can include a Chromium (Cr) seed layer. This seed layer is configured to nucleate the alpha-Tantalum layer 152 during sputtering. This is subsequently described in greater detail.

In embodiments, the devices 100, 150 of FIGS. 1A-1B can be configured to form a MEMS device including a thermal actuator. The devices 100, 150 can include a silicon substrate 162, a α-Tantalum film 152 forming a plurality of leg pairs 106a-b, the leg pairs 106a-b extending from a first side 102a of the α-Tantalum film or a second side 102b of the Tantalum film to a central shuttle 104 suspended above the silicon substrate 162. The first and second sides 102a-b are affixed to the silicon substrate by at least one underlayer 154 and 156. The plurality of leg pairs 106a-b are configured for in-plane deflection relative to the silicon substrate 162. In this example, each leg of the plurality of leg pairs is at least 150 μm long, 2.5 μm thick, and 1 μm wide. In this example, each leg of the plurality of leg pairs comprises a sidewall profile having approximately no lateral etch (e.g., about a 90° etch angle). The underlayer includes a thermal SiO₂ sacrificial layer, a Chromium hard mask, or both. Each leg of the plurality of leg pairs is configured for a 5 μm offset of the central shuttle in a deactivated position and up to a 10 μm offset of the central shuttle in an activated position.

FIG. 1D shows an example process 190 of forming a Ta structure (shown by Ta 203) directly on a CMOS structure including Cu vias 201, which can connect directly to CMOS structures disposed in an oxide (e.g., SiO₂). As previously described, the relatively low temperature processing (e.g., <100° C.) of forming the Ta structure 203 on the oxide substrate 204 enable the Ta structure to be formed directly on CMOS structures. The Ta layer structure 203 can thus form a MEMS structure that is electrically coupled to a CMOS structure with lower parasitic capacitance than that of a MEMS structure that is formed separately from the CMOS structure and later connected (e.g., with additional, longer metal leads). Generally, the entire area on an IC above the CMOS structures is available for forming MEMS structures, unlike many integrated processes where there is no CMOS in areas where the MEMS are located. This results in higher area utilization for MEMS devices including CMOS ICs. Thus, a CMOS+MEMS combined IC package can be formed.

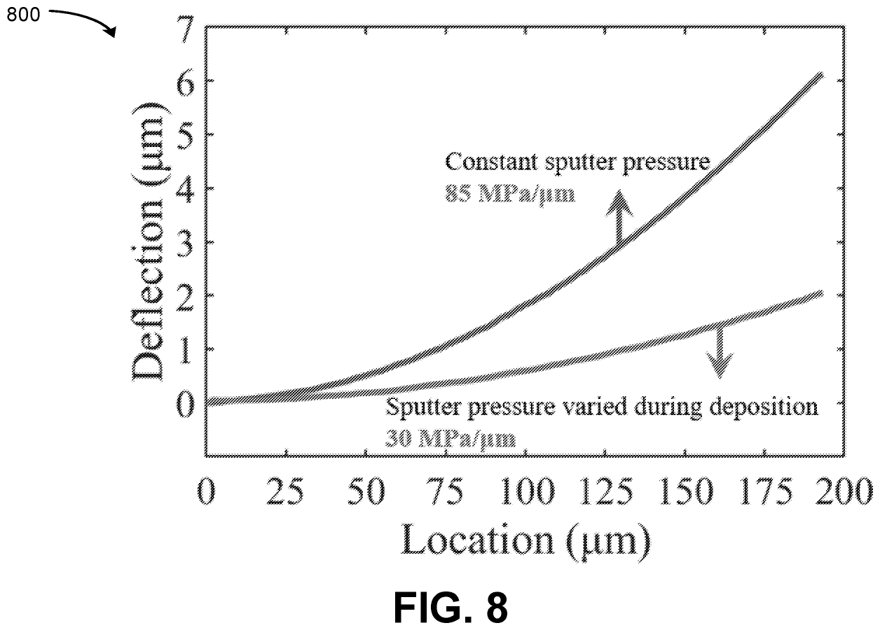

The control of residual stress and control of residual stress gradient (e.g., as described in relation to FIG. 8) show that Ta structures 203 can be configured to bend up or down in a resting (non-actuated) state. For example, the Ta structure 203 can include a cantilevers configured to bend down toward the oxide 204. Flat fingers as used in accelerometers and gyroscopes can thus be formed using the process 200.

The mass density of Ta is high compared to polysilicon (˜7 times denser). Ta is thus more sensitive (e.g. in accelerometers) to actuation signals.

As shown in FIG. 1D, Cu 201 is a CMOS metal. Below the Cu are CMOS transistors. After the top layer of Cu 201 is deposited, the Ta layer is deposited directly over it. At step (a), an AlN sacrificial layer depositing and patterning is performed. At step (b), an α-Ta deposition and Chromium 205 mask pattern are formed. At step (c), an α-Ta reactive ion etch (RIE) is performed to etch portions of the α-Ta layer, as subsequently described. At step (d), a release (removal of the sacrificial layer) and critical point drying (CPD) are performed to render the Ta structures freestanding over the substrate (including CMOS transistors).

Turning to FIG. 2A, top views of the MEMS device 100 of FIGS. 1A-1B are shown. An actuated state 220 of the device 100 is shown with current I applied to the first and second fixed portions 102a-b and configured to flow through legs 106a-b. The shuttle 104 is moved in-plane relative to the Si substrate as denoted by the actuation arrow labeled “actuation.”

A relaxed state 210 of device 100 shows the legs 106a-b in a relaxed state without an actuation signal applied. A leg offset δᵢ (e.g., δᵢ=5 μm) is shown, which is included through design. This causes the actuator to move in the offset direction (e.g., for in-plane motion or other motion). The leg offset δᵢ can change as a result of residual stress in the Ta structure. For example, if the stress is tensile, after release, δᵢ is less than 5 μm. For example, if the stress is compressive, after release, δᵢ is greater than 5 μm. When the device 100 is actuated, there is further displacement. If the residual stress is not controlled (e.g., as descried herein), the displacement can be inaccurate from an expected value and result in an inaccurate sensor.

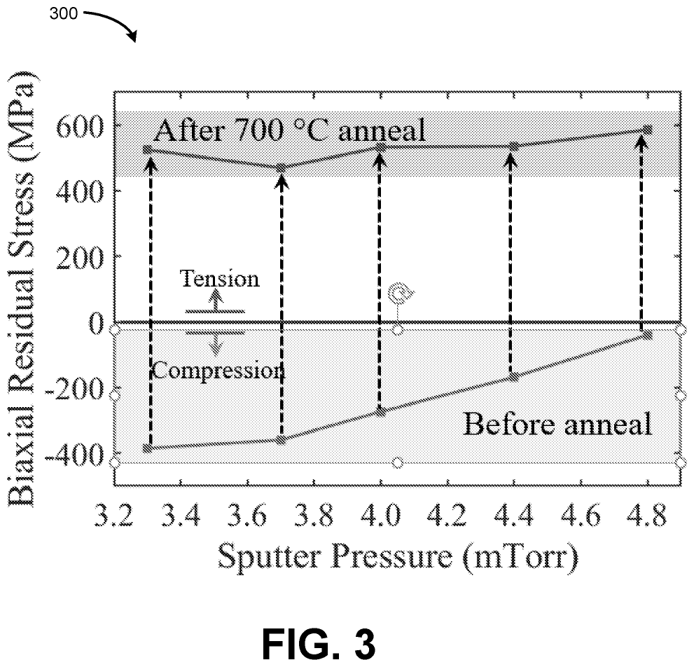

Device 100 is a V-shaped or chevron style thermal actuator. The inclined legs 106a-b (or beams) are arranged in parallel. The legs 106a-b generate rectilinear deflection by thermal expansion, responsive to current or heat. Device 100 is actuated using Joule heating. The modeled PS and Ta TAs have two leg pairs with leg length L=150 μm and offset δᵢ=5 μm. This leg 106a-n geometry is used for generating results related to FIGS. 3-9.

To compare the actuation voltage and power consumption of Ta and PS TAs, the steady-state behavior is estimated with a simplified 1-D heat flow condition. This lends perspective to the relative performance of the two materials. However, actuation by Joule heating is inherently a complex multi-physics problem. Therefore, a coupling electro-thermo-mechanical model is utilized to predict TA behavior as further validation. For self-actuation, analytical solutions are available, and a finite element analysis (FEA) model is described below.

For actuation by Joule-heating, assume a zero^{th} order model in which the power P is the same for Ta and PS TA legs of the same cross-sectional area A and length L. Then

$$P = \frac{{V}^{2}}{R} = \frac{{V}_{Ta}^{2}}{{ρ}_{Ta} ( L / A )} = \frac{{V}_{PS}^{2}}{{ρ}_{PS} ( L / A )} \qquad ( 1 )$$

where V is the applied voltage, R is electrical resistance and ρ is the electrical resistivity. The subscripts Ta and PS denote the tantalum and PS actuators, respectively. The (L/A) terms cancel. Measured data gives ρ_{Ta}=20 μΩ·cm and ρ_{PS}=2000 μΩ·cm.

For a small gap between the legs and the substrate, the major source of heat loss in gaseous atmosphere is through thermal conduction from the legs to the substrate, and depends only weakly on the TA material. For the same power, the increase in actuator leg temperature, ΔT, is approximately the same. However, α_{Ta}≈6 με/° C. while α_{PS}≈3 με/° C. Therefore, for the same power delivered, the Ta TA will deflect twice as much as the PS TA. If the Ta TA power P is halved, its deflection will be the same as that of the PS TA. Thus, P_{Ta}/P_{PS}=0.5. Including this consideration, rearranging Eq. (1) and inserting numbers,

$$\frac{{V}_{Ta}}{{V}_{PS}} = \sqrt{( \frac{{P}_{Ta}}{{P}_{PS}} ) ( \frac{{ρ}_{Ta}}{{ρ}_{PS}} )} = \sqrt{( \frac{0.5}{1} ) ( \frac{20}{2000} )} \approx \frac{1}{14} \qquad ( 2 )$$

Therefore, to zeroth order, for the same deflection, a Ta TA will operate at half the power and 14 times lower voltage than the PS TA. As PS actuators typically operate at 5-10 V, Ta TAs will operate at 0.5-1 V. In cross section, the leg thickness t is 2.5 μm while the width w is 1 μm. These are chosen because a leg width of 1 μm is within optical lithography capabilities, ensuring a well-controlled output force, which is highly sensitive to the change in leg width. Additionally, a critical out-of-plane buckling stress, σ_{c}^{op}, is higher than the critical in-plane buckling stress, σ_{c}^{ip} to ensure the desired in-plane motion. A worst-case scenario, such as a beam offset angle θ=0, is analyzed for two beams that are mirrored and connected at the shuttle. For unconstrained actuation, a sufficient condition is t>w. From experience, t>1.5w is preferred. However, the ratio t:w increases further if the in-plane motion of TA is constrained. For example, during nanomechanical tensile testing, TAs are used to apply load and their in-plane motion is constrained by the specimen. For constrained in-plane motion, the effective length of the legs doubles and then

$$\frac{{σ}_{c}^{op}}{{σ}_{c}^{ip}} \approx \frac{{π}^{2} {Et}^{2} / ( 3 \cdot {( 2 L )}^{2} )}{{π}^{2} {Ew}^{2} / ( 3 \cdot {( L )}^{2} )} = {( \frac{t}{2 w} )}^{2} \qquad ( 3 )$$

Hence, the film thickness t is at least twice the beam width w to deter out-of-plane buckling. Therefore, t=2.5 μm is chosen to guarantee in-plane motion for an aspect ratio of 2.5:1. Then, σ_{c}^{op}≈1.6·σ_{c}^{ip}.

The actuation voltage and current to achieve a targeted displacement of the shuttle is more accurately predicted using the coupled model. The Ta-to-PS actuation voltage ratio is found to be 1:16 in comparison with 1:14. This is mainly because the real CTE ratio, α_{Ta}:α_{PS}, is more than 2:1 (α_{Ta}=6.3 με/° C. and α_{PS}=2.5 με/° C. at room temperature). The actuation voltage ratio is found to be independent of displacement. The 16× lower voltage of Ta TAs means these actuators can operate at 0.3 V for a measured displacement of 1.5 μm, which makes them compatible with CMOS (≤1.8 V). Also, the power consumption is decreased by 60%, in comparison with the zero^{th} order model decrease of 50%. These results are seen in graph 240 of FIG. 2B, where the actuation voltages and power consumptions of PS and Ta TAs at different maximum displacements are presented, and the predicted data discussed herein are circled.

The temperature change due to joule heating is not uniform along the TA legs. While the anchors are at room temperature, the maximum temperature generally occurs at a location between the anchors and the shuttle. A high operating temperature can lead to softening, plastic deformation or creep of the structural material. In air, oxidation can affect the maximum temperature. Therefore, a smaller increase in temperature while maintaining the desired displacement/force output is important for achieving reliable TAs. Due to its higher CTE, Ta actuators experience less than one half of the maximum temperature change compared to PS. For a measured displacement of 1.5 μm, Ta TAs operate at a temperature change of around 75° C. This is much lower than Tₘ/3, above which creep is generally assumed to initiate for metals. The maximum temperature change along the thermal legs is presented in graph 250 of FIG. 2B, and the predicted data discussed are circled.

Self-actuation is achieved by raising the ambient temperature, leading to a uniform temperature in the actuator legs. Only one actuator leg pair is considered as the displacement does not depend on the number of legs. Boundary conditions include fixed constraints at two ends of the leg pair (anchors) and a temperature change. The displacement of the shuttle, δ, due to a homogeneous temperature change, ΔT, can be also obtained analytically from

$$δ = αΔ TL \frac{sin ( θ )}{( {sin}^{2} ( θ ) + {cos}^{2} ( θ ) \frac{12 I}{{AL}^{2}} )} \qquad ( 4 )$$

where α is the effective CTE, and I=tw³/12 is the moment of inertia of the actuator leg cross section, A=wt is the leg cross-sectional area, and θ is indicated in FIG. 2A.

Ta has important advantages over PS as a TA structural material because Ta exhibits 16× lower driving voltage, compatible with CMOS, 60% lower electric power consumption, 50% lower operation temperature for the same displacement, and the capability of self-actuation.

Ta can be integrated into a conventional MEMS fabrication process flow as a structural material. The electro-thermo-mechanical model uses bulk Ta material properties. When deposited directly onto thermally grown oxide, Ta assumes the tetragonal β-phase, as indicated by a relatively high resistivity of ρ=173 μΩ·cm. This high ρ phase (170-210 μΩ·cm) is of interest in thin film resistors and heaters, and is also a potential material for magnetoresistive random access memory technologies. As the sputter pressure decreases, energetic particle bombardment is intensified and results in a higher compressive residual stress. For repeatable operation, a lack of intrinsic (or growth) stress change is needed at potential operation temperatures. However, the compressive stress in β-Ta is fully relaxed and a tensile biaxial residual stress, σ_{R}^{b}, of 400-600 MPa results after a 700° C. anneal. This anneal is performed in an argon-purged rapid thermal anneal (RTA) chamber at atmospheric pressure. To minimize oxidation, the Ta is covered by a 1-μm thick PECVD SiO₂, which is stripped by RIE after anneal. Graph 300 of FIG. 3 presents σ_{R}^{b} values of blanket β-Ta films deposited from 3.3 to 4.8 mTorr before and after anneal.

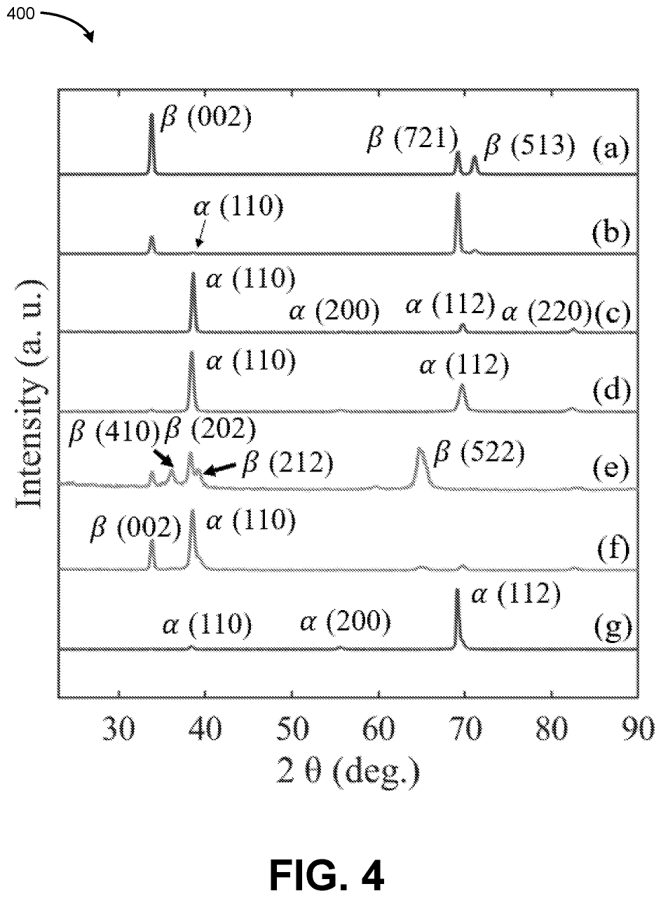

The σ_{R}^{b} change results from a β-to-α phase transformation. The X-ray diffraction (XRD) diagram in FIG. 4 confirms that as-deposited films are pure tetragonal β-phase. Upon a 20 min anneal at 500° C., β-Ta partially transforms to α-Ta, as shown in line b. When the temperature is raised to 700° C., the β-to-α phase transformation is complete within 10 min, as shown in line c. This phase transformation causes the film to contract due to the difference in β- and α-phase densities and due to significant grain growth ³⁰. As the contraction is constrained, high tension results.

To avoid the phase transformation, the more stable bcc α-Ta is preferred. It also exhibits a low ρ of 15-60 μΩ·cm, making it an attractive choice for lower power TAs. The α-phase can grow on a 10-nm-thick Cr seed layer. Its bcc unit cell is confirmed by the XRD diagram of line d and ρ=21.4 μΩ·cm is measured. However, a freshly prepared seed layer is essential to grow α-Ta. If the vacuum is broken between Cr/Ta deposition, then Ta grows in the pure β-phase (line e). This is likely due to the immediate oxidation of Cr when exposed to air. By sputter cleaning the substrate with a bias voltage of −40 V for 45 s after vacuum is broken, a mixture of α- and β-phases with ρ=30.0 μΩ·cm is obtained, with the most intense peak from α-Ta (line f). Likely, the sputter clean removes most chromium oxide but residue remains. Therefore, successive Cr/Ta depositions or a sufficiently long sputter-clean step is needed to avoid formation of β-Ta.

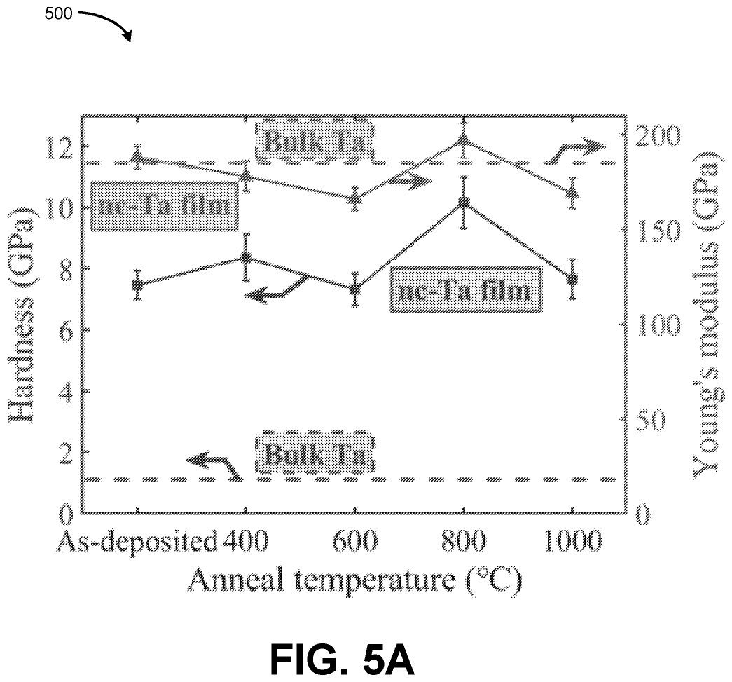

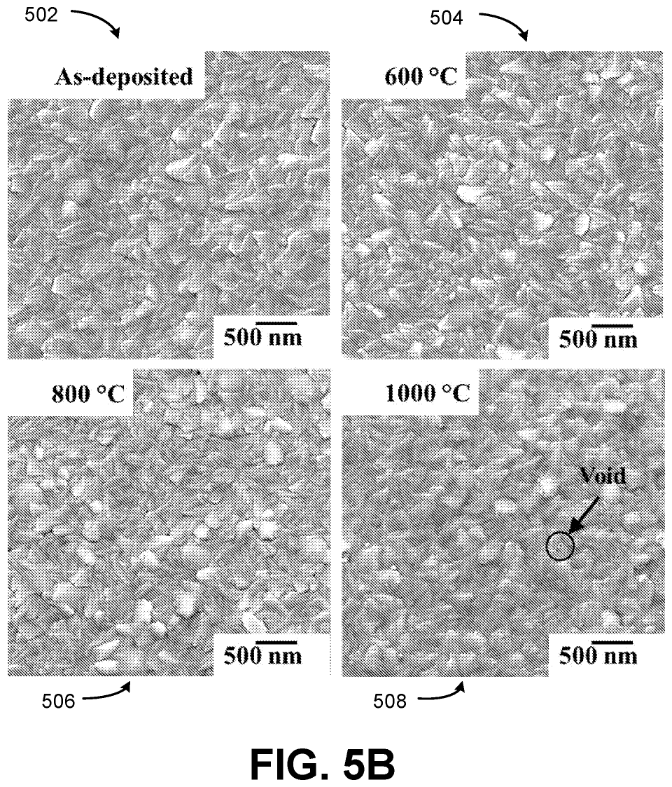

For hardness enhancement, the strength of α-Ta films is significantly enhanced over bulk Ta, as now described. The nanoindentation hardness, H, is 7.47±0.46 GPa at RT. This corresponds to a yield strength σ_{y}≈H/3=2.5 GPa, ten times greater than bulk Ta. Therefore, even at a deflection of 4 μm, the maximum bending stress of approximately 600 MPa, as shown in graph 250, remains well below σ_{y} with a safety factor of about 4. A Young's modulus of 188±6 GPa is also measured at RT, comparable to that of bulk Ta, 185 GPa ³⁴. The hardness and Young's modulus of α-Ta films is measured ex-situ after anneals at atmospheric pressure from 400-1000° C. in the argon-purged RTA chamber. These properties are stable even after an anneal at 1000° C. H measurements, along with bulk Ta data of RT, are shown in graph 500 of FIG. 5A.

This strength enhancement arises from the fine-grained microstructure. Top views 502, 504, 506, and 508 of Ta films in the as-deposited condition and after anneals are shown in FIG. 5B. According to the Hall-Petch relationship, nanocrystalline Ta should have higher σ_{y} than bulk Ta, which can have a grain size on the order of several hundred micrometers. Guisbiers et al. obtained a Hall-Petch coefficient of 58 GPa nm^{1/2} by measuring the hardness of Ta films with different grain sizes. Based on this strengthening coefficient, the measured hardness of 7.47 GPa for as-deposited films corresponds to an average grain size of approximately 160 nm, which is in reasonable agreement with views 502, 504, 506, and 508 of FIG. 5B. Although no obvious change in grain size is observed after 600° C. and 800° C. anneals of views 506 and 508, respectively, voids are formed after 1000° C. anneal of view 508.

The lack of noticeable grain growth is due to low homologous temperature, i.e., at T=800° C., T/Tₘ=0.33, the relatively short 30 min anneal time, and the inferred grain size of 160 nm. The larger initial grain size in Ta and the shorter anneal time indicate that the lack of grain growth inferred here is not unreasonable. Also, an increased electrical resistivity of 22.5 μΩ·cm and 27.0 μΩ·cm (compared to 21.4 μΩ·cm) is measured after anneals at 800° C. and 1000° C., respectively. Since Ta resistivity increases with oxygen content, possibly trace oxygen is incorporated into the film during anneals, leading to pinning of grain boundaries. Peak broadening cannot be detected in X-ray analysis due to the relatively large grain size. However, the anneals do result in a change in the preferential orientation. Compared with the XRD diagram of as-deposited films (line d of FIG. 4), the (112) orientation becomes increasingly dominant as the anneal temperature goes up. The films remain α-phase and no new phase is formed.

For residual stress control, as mentioned above, post-deposition anneal is usually needed to reduce PS residual stress. However, the biaxial residual stress σ_{R}^{b} of sputter deposited α-Ta can be well controlled during deposition by adjusting the sputter pressure. A compressive σ_{R}^{b} is observed at lower sputter pressures due to enhanced energetic particle bombardment ³². It increases linearly with pressure and becomes tensile at a critical sputter pressure of ≈4.8 mTorr. The σ_{R}^{b} versus sputter pressure slope is shallower than the steep stress change for Ta about the critical sputter pressure reported by Thornton et al. This makes it easier to achieve near-zero stress, allowing for greater process margin.

The Coefficient of thermal expansion (CTE) is used to predict TA behavior. For cubic materials, CTE is isotropic. In each cycle, the film deforms thermoelastically and the slopes are constant and nearly identical from RT to 150° C. Based on Eq. (6) below, the average Δα of heating and cooling stages is 3.2 ε/° C. Using α_{Si} of 2.7 με/° C., ara is determined to be 5.9 με/° C. This is in good agreement with the published bulk Ta CTE of 6.3 με/° C.

Reactive ion etching (RIE) is generally used for etching processes. A technical obstacle, arising from the large aspect ratio of 2.5:1 of the TA legs, is vertical etching of the sidewalls. Such a large thickness-to-width ratio can possibly cause severe lateral etch. This could lead to a loss of shape and of leg width, which can change the output force of TAs. It is known that α-Ta is more difficult to pattern using RIE than p-Ta. Due to the high volatility of Ta fluoride and chloride, Ta can be etched by conventional plasma etching based on fluorine, chlorine, or interhalogen compounds. However, this has generally been performed for β-Ta or unpatterned α-Ta films. The thickest reported α-Ta feature patterned by conventional RIE with sidewall protection (e.g., etch angle greater than 80°) is 100 nm. This was using a SiCl₄—NF₃ gas mixture which is not typically available. Thicker α-Ta structures of 350-400 nm were also etched, but patterned by unconventional electron cyclotron resonance ion stream with a mixture of chlorine and fluorine gases.

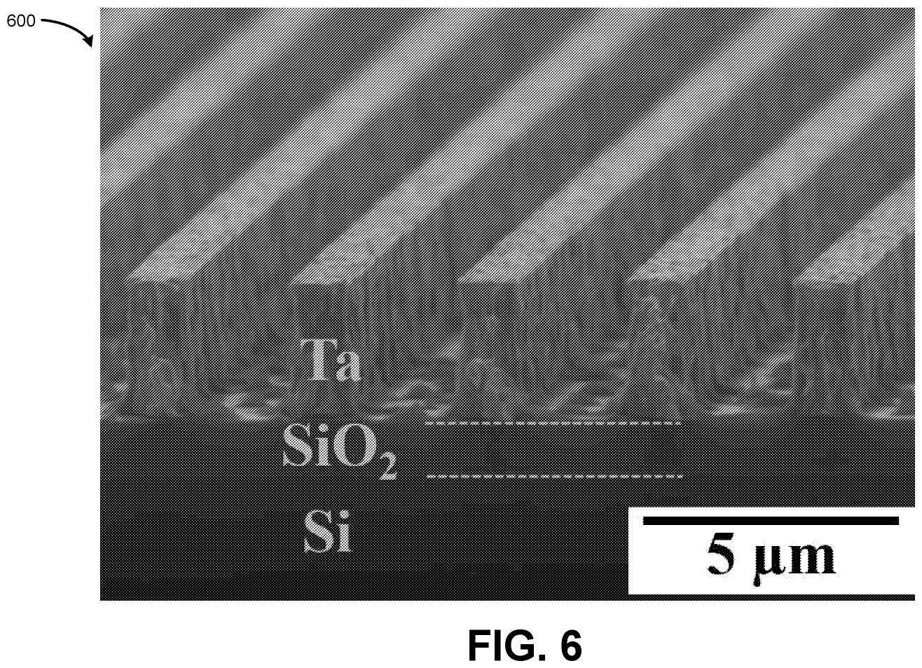

Using fluorine-based RIE, an extensive scoping is performed to improve sidewall protection for the 1 μm feature. O₂, which is often added to the etch chemicals to release more fluorine and to boost etch rate, can actually greatly enhance lateral etch. In contrast, the addition of Ar improves anisotropy. α-Ta exhibits a significant macroloading effect: side wall protection is generally much better for a wafer than a chip. Other process parameters, including pressure, gas flow and power, are also found to influence the extent of the lateral etch. There is minimal lateral etch and a vertical side wall profile after a 1 hour of RIE, shown in image 600 of FIG. 6 under the optimal conditions. The example conditions for Ta RIE are: CF₄ flow 6 sccm, Ar flow 30 sccm, pressure 20 mTorr and power 44 W.

A full fabrication sequence is now described. Thin film α-Ta possesses the properties required for a promising thermal actuator material and importantly that it can be processed by conventional MEMS fabrication methods. Therefore, a full fabrication sequence for Ta TAs is performed.

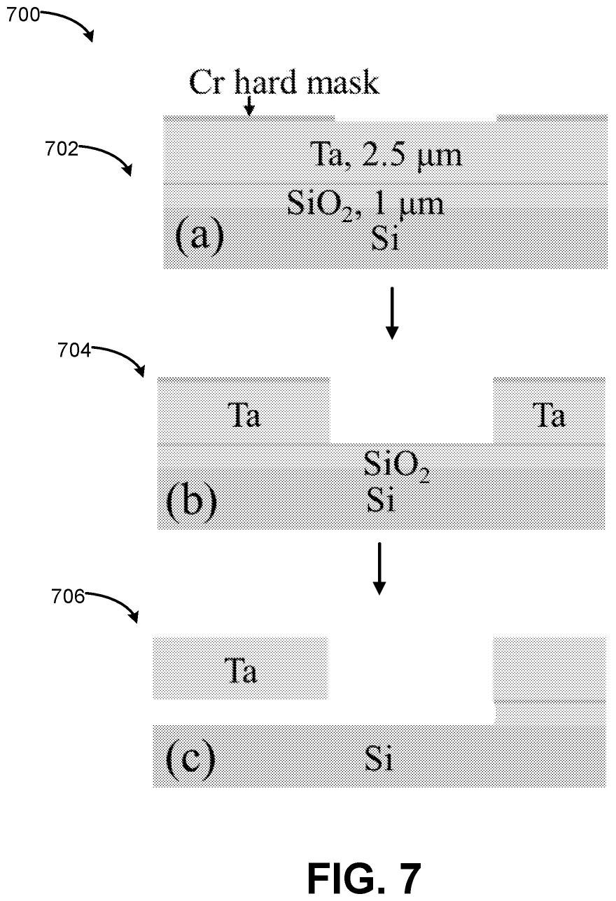

The proposed full fabrication process flow is shown in process 700 of FIG. 7. At step 702, following deposition of a 2.5 μm thick α-Ta film, a 45 nm thick Cr is deposited as an etch hard mask. Because the hard mask is thin, a positive photoresist of only 400 nm thickness can be used to maximize resolution. The Cr hard mask is ion milled, as assisted by end-point detection to avoid any re-deposition effect, and the photoresist is stripped by a gentle oxygen plasma.

At step 704, the Ta film is RIE'd using CF₄ and Ar. The etch rate is approximately 42 nm/min. Subsequently, at step 706, the Cr hard mask is stripped selectively by Cr wet etchant, followed by the removal of the sacrificial thermal oxide at room temperature by buffered hydrofluoric acid (BHF, 5 parts 40% NH4F:1 part 49% HF) for 1 hour. Critical point drying (CPD) renders the structures freestanding.

At a constant sputter pressure the stress gradient is 85 MPa/μm, shown in graph 800 of FIG. 8. This causes unacceptable curvature in the shuttle, as it contacts the substrate. Therefore, during the Ta deposition step, the sputter pressure is varied during deposition to balance the intrinsic stress gradient. The stress gradient can be determined from the tip deflection of cantilever beams, δ using

$$\frac{d {σ}_{R}^{u}}{dz} = \frac{E}{1 - v} \frac{2}{{l}^{2}} δ \qquad ( 5 )$$

where l is the beam length, σ_{R}^{u} is the uniaxial residual stress and z is the out-of-plane direction. The tip deflection is measured by interferometry. The cantilever beam bends up, meaning the stress shifts towards tension as the film deposition continues. Results for “varied sputter pressure” are shown in graph 800 of FIG. 8. By utilizing decreasing sputter pressures, the stress gradient reduces to 30 MPa/μm and the tip deflection is almost 3 times smaller. As sputter pressures both higher and lower than the critical sputter pressure are used, the average σ_{R}^{b} of the as-deposited blanket Ta film remains at a low level of approximately −40 MPa. With this sequence, the released TA shuttle becomes free standing. The stress gradient is measured after a hydrogen degas anneal, as will be explained next.

After the BHF release step, the residual stress shifts strongly towards compression. The residual stress changes increase linearly with BHF exposure time, and reach −1 GPa after 150 minutes. This is because during the release step, BHF injects atomic hydrogen into the film, which expands the crystal structure and results in compressive stress. To remove hydrogen and recover the as-deposited residual stress, the device is degassed at 500° C. in ultra-high vacuum (UHV). This anneal leads to a change in the preferential orientation of the film (line g of FIG. 4). After degas, the stress, which is extracted using fixed-fixed beams, is largely recovered but still 50-60 MPa more compressive than the initial stress.

Following the process 700, α-Ta TAs are successfully fabricated. The TA device 900 shown in FIG. 9 has 16 leg pairs, with the same leg geometry as in FIG. 1A-1B. TA legs with this geometry are used for characterization.

The thermal actuator characterization is now described. For the as-released structure, large and unexpected in-plane TA displacements of ˜12 μm were initially observed after release, shown in device 900 of FIG. 9. This corresponds to a residual compressive stress of 1.24 GPa. With a post-release UHV anneal, the in-plane displacement after release is approximately 5 μm, corresponding to a stress of −340 MPa. The TA is fabricated using a blanket Ta film with a uniaxial stress of about −27 MPa. Therefore, the stress change after the UHV anneal is about −310 MPa, higher than that measured in fixed-fixed beams (−60 MPa). The reason is likely that TA legs are much narrower (1 um wide) than fixed-fixed beams (10 or 20 μm wide) and have a higher surface-to-volume ratio. This makes the legs absorb more hydrogen than the wide fixed-fixed beams, meaning that more hydrogen may remain in the film after UHV.

It is observed in FIG. 6 that the Ta RIE leaves behind residue between the lines. Generally, small islands are swept away during the release process and as such that the appearance of chips is clean, as seen in FIG. 9.

For actuation by Joule heating, the displacements now described herein are in-plane and are with respect to the displacement after release. The displacements are measured as a function of current in air and compared to electro-thermo-mechanical model results. A Vernier scale is imaged under a 50× objective during actuation and is used to determine the displacement of the shuttle by pattern matching, which has a resolution of approximately 5 nm. Ta is susceptible to internal oxidation, and oxidation at 100° C. occurred without protection. The measurements reported are performed with the TAs protected by a 20 nm thick Al₂O₃ passivation layer deposited by atomic layer deposition (ALD), which raises the oxidation resistant temperature to about 150° C. While further improved passivation is a topic for future research, in high vacuum as can be achieved in test chambers ⁴⁹ or electron microscopes, the operating temperature is likely substantially higher (e.g., minimal oxidation up to 750° C.).

The displacement of a TA as a function of current per leg for five actuation cycles is plotted in graph 1000 of FIG. 10 (solid line, diamond markers), along with the model results (dashed line, square markers). Repeatable actuation for five actuation cycles is demonstrated. Measurements show agreement with the model up to 6.3 mA/leg, but displacement is enhanced at higher current levels. This is due to a higher actual leg temperature than the modeled temperature, as explained next. The model considers widely spaced leg pairs and assumes they are thermally isolated from each other, as is valid when the separation is approximately 100 μm or more. However, the heated leg pairs are spaced by only 10 sm. This leads to less efficient heat dissipation and an overall higher leg temperature for a given current. The effect becomes increasingly important as heat generation increases at high current.

Additionally, the actuation voltage and electric power consumption are measured as a function of current per leg. They are also predicted by the electro-thermo-mechanical model previously described using the measured Ta thin film properties. The as-fabricated TAs have 16 leg pairs while only two leg pairs are modelled, so the measured power consumption is divided by 8 to normalize this difference. These results are plotted in graph 1002 of FIG. 10. An overall agreement between measurements and the model is evident. The measured actuation voltage and power are slightly higher at high currents due to the self-heating effect as explained before, which slightly raises the electrical resistivity. The low power consumption and actuation voltage (below 0.35 V) of Ta TAs are confirmed by these measurements.

The repeatable results indicate that Ta oxidation is a minor issue up to the estimated maximum leg temperature (including self-heating) of 120° C. Including the residual stress inferred from the 0 V displacement, the maximum operating stress in the legs is approximately +500 MPa (tension) and −610 MPa (compression). Similarly, the strength of the nanocrystalline Ta is well above the operating stress.

Self-actuation is tested in air on a hot plate using optical microscopy and displacements are again measured using a Vernier scale. Temperature calibration is necessary because heat transfer is imperfect. To do this, the resistivity of actuator legs in-situ was measured using the four-point probe configuration. By knowing the temperature coefficient of resistance (TCR) of Ta, +3800 ppm/° C. ⁵¹, the actual temperature of the TA legs, T_{act}, is deduced after waiting 15 min to establish a steady state condition at each setpoint temperature, Tₛₚ. Above the reference temperature at RT, it is seen that T_{act} is approximately 60% of Tₛₚ, revealing the critical importance of calibration. The T_{act} values are plotted in graph 1004 of FIG. 10.

An effective CTE of Δα=3.2 με/° C., i.e., the difference between the CTEs of Ta and the Si substrate, is used for models. FEM model results are essentially identical to the analytic model. For measurements, the temperature is stepped up in increments of 10° C. Over the range from RT to 150° C., the agreement with the model is good. The measured self-actuation in-plane displacement as a function of T_{act} and the analytic model are shown in graph 1006 of FIG. 10.

For this specific TA design, the temperature sensitivity is approximately 14 nm/° C. This can be adjusted by changing the TA leg geometry and further improved by certain amplification designs such as cascaded structures for different applications. In this example, the substrates used are 4′ (100) Si wafers with 1 μm thick thermally grown oxide. A load-locked DC magnetron sputtering system is used to deposit Ta films at a base pressure lower than 7×10⁻⁸ Torr without intentional heating or biasing using Ar as the working gas. At a power of 250 W, the deposition rate is approximately 19 nm/min. Crystal structures are determined on blanket films using X-ray diffraction (XRD) under conventional reflective configurations, with a copper K_{α} source operated at 45 kV and 40 mA (Philips X'pert Pro MRD, model no. PW3040/60). Resistivity is measured using a standard four-point probe configuration. Young's modulus and hardness are determined by nanoindentation. Based on the Stoney equation, the biaxial residual stress σ_{R}^{b} is found by measuring the curvature change of substrates before and after deposition using a laser scanning method. The CTE of Ta is determined using the same tool and method by measuring the stress change as the temperature goes from room temperature (RT) to 150° C. The relationship between biaxial stress change, Δσ_{R}^{b}, and temperature change, ΔT, is as follows

$${Δσ}_{R}^{b} = \frac{E}{1 - v} ΔαΔ T \qquad ( 6 )$$

where E and ν are the Young's modulus and Poisson's ratio of films, respectively, and Δα is the difference of CTE between Ta and Si substrates. The CTE of single crystalline Si is well known. Therefore, the CTE of Ta films can be determined by plotting Δσ_{R}^{b}−ΔT and finding the slope.

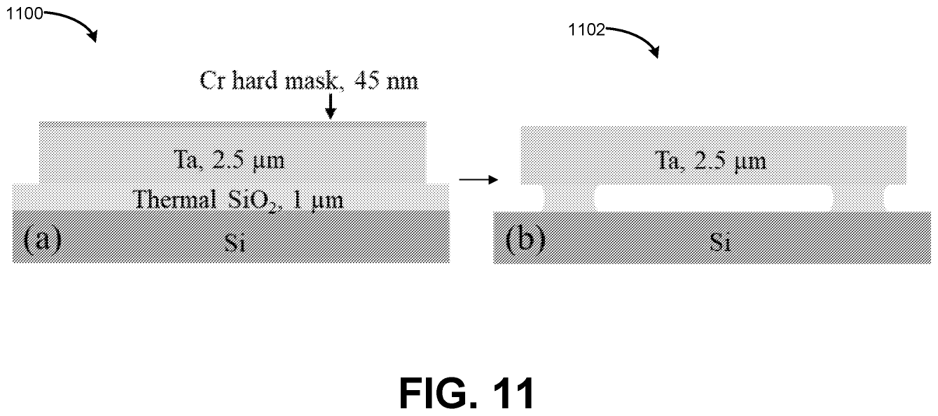

Turning to FIG. 11, compression and decompression of structural tantalum films exposed to buffered hydrofluoric acid is now described. As a refractory metal with a high melting temperature, high mass density and large coefficient of thermal expansion, Ta is of great interest as a structural material in MEMS. One of the major issues with any freestanding structure, however, is the control of residual stress. Suspended fixed-fixed beams made from Ta films under tension buckle after a buffered hydrofluoric (BHF) acid release step, implying a large change of stress towards compression. The change in uniaxial stress is proportional to BHF exposure time and reaches −1 GPa after 150 minutes. Although there are many sources of residual stress in metal thin films, hydrogen (H) injection due to BHF is the major cause of this change. Residual stress can be largely recovered by degassing at 500° C. in a high vacuum environment.

In MEMS applications, low residual stress is often needed to achieve the required function and residual stress control is required to accurately predict device performance. For instance, a low average stress and stress gradient are desirable for RF switches. Residual stress also affects the dynamic response of Ta clamped-clamped beam structures. Stress control is a complex issue in metal thin films, where residual stresses are strongly dependent on deposition conditions and on subsequent thermal treatments. A large shift, not precisely quantified but on the order of hundreds of MPa, in Ta fixed-fixed beams towards more compressive stress has been measured.

To be able to use Ta in MEMS, the underlying mechanism responsible for this stress change must be clarified, and methods to prevent or reverse it must be found. By detecting species outgassing from BHF-treated Ta films using a quadrupole mass spectrometer, the compressive residual stress after a BHF etch arises from atomic hydrogen incorporation into the Ta film from the weak acid. Hydrogen can be removed by a degassing procedure, and the original residual stress can largely be recovered.

The substrates used are 4″ (100) Si wafers with 1 μm thick thermally grown oxide. Ta films are sputtered onto the substrate to a nominal thickness of h_{f}=2.5 μm, a typical thickness for surface micromachining structural materials, in a load-locked DC magnetron sputtering system (CVC Connexion Cluster Tool) at a base pressure lower than 7×10⁻⁸ Torr without intentional heating or biasing. At a power of 250 W, the deposition rate was approximately 19 nm/min. Sputter deposition of a 45 nm thick Cr follows, which serves as the hard mask for Ta etch. The Cr mask is patterned using photolithography and ion milling. The Ta film is then reactively ion etched (RIE'd). At this point, the cross-section is schematically represented in FIG. 11 at step 1100. Next, the Cr hard mask is stripped. Then the sacrificial oxide is removed at room temperature by BHF (5 parts 40% NH₄F:1 part 49% HF). Finally, critical point drying renders the structures freestanding, shown in FIG. 11 at step 1102. The fabricated fixed-fixed beams have widths of 10 or 20 μm and lengths of 100, 250, 500, 750 or 1000 μm.

The change in curvature due to the Ta deposition of each wafer is conveniently measured during the process flow (e.g., using a Tencor Flexus tool (FLX-2320)), and the biaxial residual stress σ_{f}^{b} is characterized by applying the Stoney equation

$${σ}_{f}^{b} = \frac{{E}_{s} {h}_{s}^{2}}{6 ( 1 - v ) {h}_{f}} ( \frac{1}{R} - \frac{1}{{R}_{0}} ) \qquad ( 7 )$$

where Eₛ, νₛ, and hₛ are the Young's modulus, Poisson's ratio and thickness of the substrate, respectively, and R₀ and R are the radii of curvature before and after thin film deposition, respectively. Crystal structures are determined on separately-deposited blanket wafers using X-ray diffraction (XRD) under conventional reflective configurations, with a copper anode operated at 45 kV and 40 mA. The Young's modulus of the blanket Ta films is found from nanoindentation. Fixed-fixed beam deflections are determined by interferometry. Resistivity is measured using a standard four-point probe configuration.

Once released, fixed-fixed beams under sufficiently high compression will buckle to partially relieve their residual stress. The critical uniaxial buckling stress for fixed-fixed boundary conditions is

$${σ}_{c}^{u} = \frac{{π}^{2}}{3} {{E}_{f} ( \frac{{h}_{f}}{L} )}^{2} \qquad ( 8 )$$

where L is the length of the beam and E_{f} is the film's Young's modulus. The buckle amplitude A is sensitive to the compressive stress, and the uniaxial residual stress δ_{b}^{u} of fixed-fixed beams before buckling can be determined by

$${σ}_{b}^{u} = - \frac{{π}^{2} {E}_{f}}{{L}^{2}} ( \frac{{A}^{2}}{4} + \frac{{h}_{f}^{2}}{3} ) \qquad ( 9 )$$

The shape of buckle profile is sinusoidal according to

$$w ( x ) = \frac{A}{2} ( 1 + cos \frac{2 π x}{L} ) , - \frac{L}{2} \leq x \leq \frac{L}{2} \qquad ( 10 )$$

where w(x) is the deflection and x is the position along the beam.

Fixed-fixed beams with lengths L=250, 500, 750 and 1000 μm are used for stress extraction. Using Eq. (9), σ_{cr}^{u} stresses are calculated to be −59.9 MPa, −15.0 MPa, −6.7 MPa, and −3.7 MPa, respectively. In this work, because the uniaxial residual stress of compressively-stressed blanket β-Ta films is −92.0 MPa (extracted using Eq. (7) and Eq. (11), described below), beams of these lengths are all expected to buckle. At this residual stress level, the critical buckling length is L_{cr}≈200 μm (Eq. (8)). Eq. (9) is accurate as long as beams have lengths greater than 1.1L_{cr}. Therefore, all the measured beams are expected to provide accurate results.

Consideration of the derivation of the Stoney Eq. (7) leads to the conclusion that it measures the average residual stress and is insensitive to the stress gradient. Likewise, rigid support posts cancel stress gradient effects in buckled fixed-fixed beams. Because the support posts in this work are relatively stiff while the measured beams are significantly longer than 1.1L_{cr}, the Eq. (9) values are also insensitive to residual stress gradient. Specimens measured using Eq. (7) reflect an average across the wafer, while those measured using Eq. (9) represent local values. Given that the sputter target is 12″ while the wafers measured are 4″, it is expected that the thickness and stress uniformity across the wafers is high.

A UHV chamber is used to measure H₂ degassing with mass spectrometry. The system base pressure is 1×10⁻⁸ Torr, while the operating pressure below 1×10⁻⁷ Torr. A 1×1 cm² piece is cleaved from a blanket Ta wafer and serves as the specimen. It can be heated and actively cooled in the temperature range 100-900 K by resistive heating and liquid N₂ cooling. The temperature is measured using 0.01″ K-type thermocouples. The specimens are heated from 300 K to 873 K at 0.25 K/s while H₂ desorption is recorded.

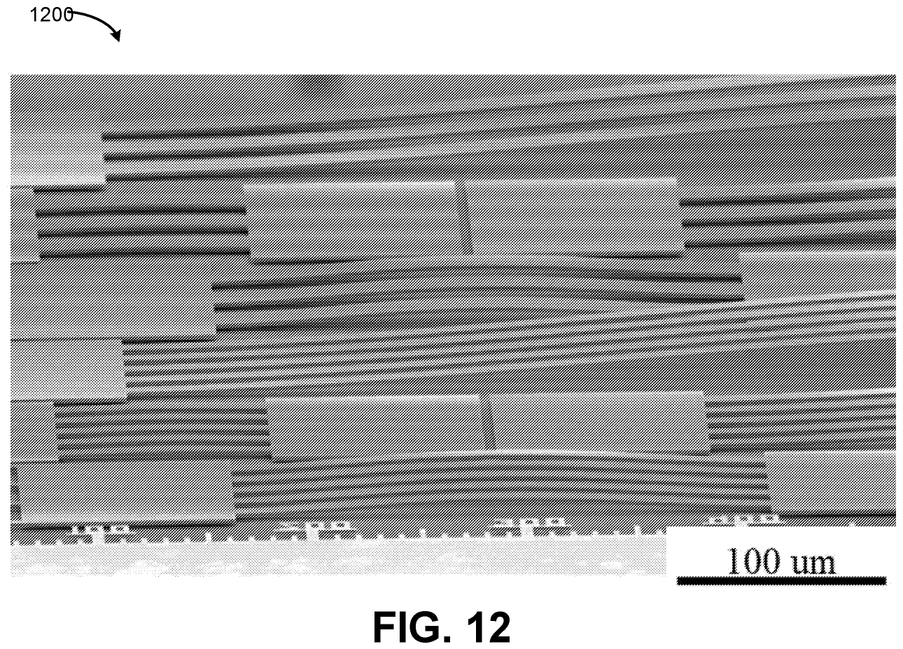

β-Ta films are used to show that hydrogen is responsible for a large residual stress change. Ta films with various initial residual stresses, spanning both tension and compression, are deposited by varying the Ar pressure. This is a well-known technique to adjust σ_{R}^{b} of sputter-deposited films as the sputter pressure can change the energetic particle bombardment intensity. After release, fixed-fixed beams made from Ta films originally under compressive stress buckle, as expected because the compressive stress is beyond σ_{cr}. However, beams made from tensile-stressed films also buckle. Image 1200 of FIG. 12 shows buckled beams that were deposited under a moderate tensile stress of 21 MPa. Therefore, the residual stress changes during the fabrication process.

Given the fabrication process flow as shown in FIG. 11, the stress change takes place either during dry etch of the Ta films or structure release. In a typical RIE, ion bombardment is an important physical process that removes etch inhibitors and enhances the etch rate. Ta films exposed to ion bombardment can exhibit a stress change towards compression. The stress change depends on the bombardment intensity, and a large change of approximately up to −3 GPa can occur. To test whether ion bombardment affects the residual stress here, the same RIE process is conducted on a 2.5 μm thick blanket Ta film covered by a 45 nm thick Cr. This mimics the environment that the un-etched Ta areas experience. The change in σ_{R}^{b} of the blanket film, from +60 MPa to +56 MPa before and after RIE, respectively, is negligible. This is likely because the bombardment only affects near-surface atoms, which is significant for the 50 nm thick film but negligible for the much thicker film here.

The stress change is caused by the release process. However, BHF is usually considered compatible with the Ta metal as it is much less aggressive than concentrated HF and the etch rate of Ta in BHF is known to be slow or zero. But it is also known that Ta can absorb a significant amount of hydrogen (over 40 atomic % H in Ta at room temperature in an H₂ pressure of 1×10⁻⁵ Torr), and a limiting composition is TaH_{1.0}. Known routes to introduce hydrogen into Ta include exposure to H₂ gas environment, electrochemical charging and H₂ plasma. If Ta does absorb hydrogen during BHF release, a compressive stress can be expected due to constrained lattice expansion.

To investigate whether hydrogen is absorbed during the release process, blanket Ta films are exposed to BHF for increasing times and measure σ_{f}^{b} before and after BHF treatment. The uniaxial stress,

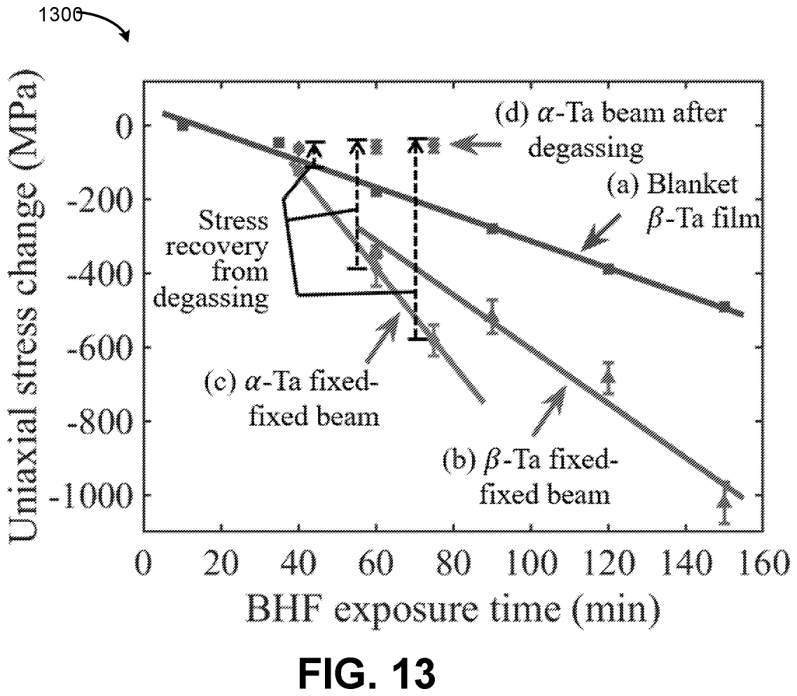

σ_{f}^{u}=σ_{f}^{b}(1−ν_{f}), (11)

where ν_{f} is film Poisson's ratio, of 6 wafers exposed to BHF for 10, 35, 60, 90, 120 and 150 min, is calculated. Based on 24 nano-indentation measurements, the Young's modulus in the as-deposited condition is 181±1.3 GPa. After 150-min exposure to BHF the same modulus was measured. The stress change increases almost linearly with BHF treatment time, and the stress increases towards compression up to 490 MPa after 150 min. The results are plotted in graph 1300 of FIG. 13 (blanket β-Ta film, line a), where a negative stress change means an increase in the compressive stress.

Similarly, longer immersion in BHF also results in a higher compressive stress in fixed-fixed beams. However, for the same amount of time, BHF has a larger effect on beam structures than blanket films, which will be explained later. The uniaxial stress variation of fixed-fixed beams (β-Ta fixed-fixed beams, blue) is also shown in graph 1300 line b, where the range indicates one standard deviation as measured from ten beams. The 10 min and 35 min data are absent as the beams are not released.

In graph 1300 of FIG. 13, stress change of blanket Ta films and fixed-fixed beams as a function of BHF exposure time are shown. Line (a) shows blanket β-Ta film, line (b) shows β-Ta fixed-fixed beam, line (c) shows α-Ta fixed-fixed beam, and line (d) shows α-Ta beam after degassing. Vertical dashed arrows denote residual stress recovery due to degassing.

An example of the fixed-fixed beam stress change extraction is now described. The buckle amplitude of an L=500 μm beam after 60-min BOE exposure is measured as 15.31 μm. Using h_{f}=2.5 μm, Eq. (9) gives a uniaxial residual stress of −434 MPa. Before the beam fabrication process, the biaxial residual stress of the as-deposited blanket β-Ta film is extracted to be −139 MPa using the Stoney Eq. (7), which corresponds to a uniaxial residual stress of −92.0 MPa using Eq. (11). Therefore, the uniaxial residual stress change after BOE exposure is −342 MPa.

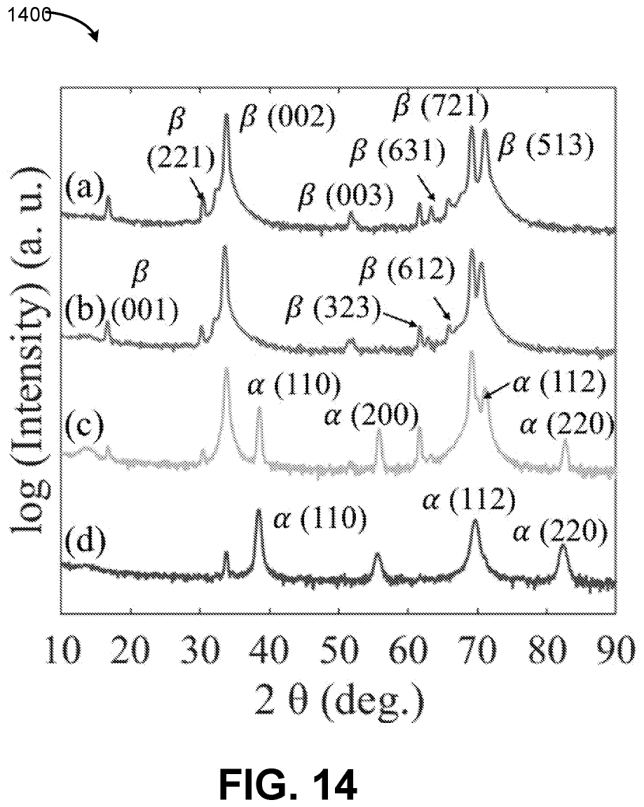

X-ray diffraction of an as-deposited blanket Ta film indicates the metastable β-phase, which has a tetragonal unit cell. A resistivity of 172 μΩ·cm is measured, also in good agreement with the known relatively high resistivity of 170-210 μΩ·cm for β-Ta. A 2.5 h BHF treatment does not lead to a phase transition or a change in texture. This observation is made by comparing line (a) of graph 1400 of FIG. 14 to line b of graph 1400.

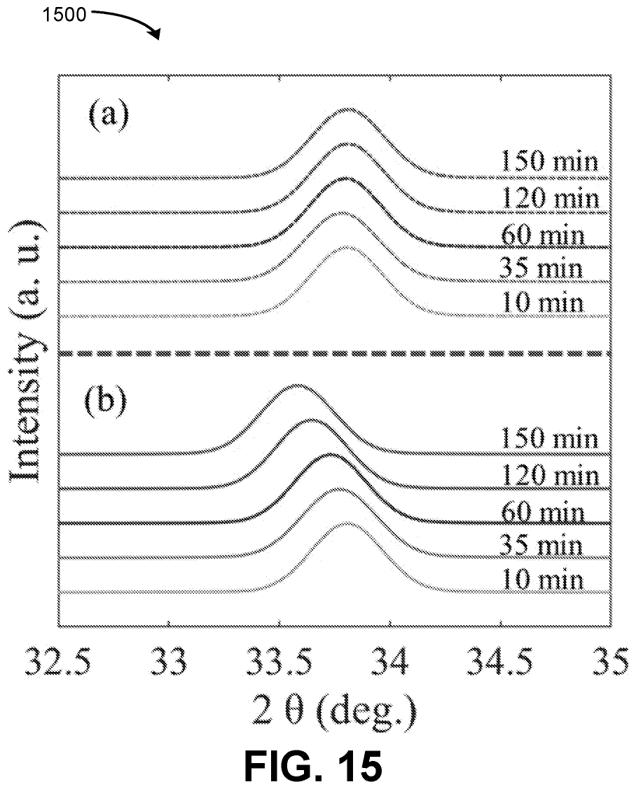

Graph 1400 of FIG. 14 shows XRD diagrams of (a) as-deposited β-Ta films, (b) β-Ta films after 2.5-hr BOE exposure, (c) β-Ta films after anneal at 500° C. for 20 min and (d) as-deposited α-Ta films on a Cr seed layer. The diffraction peaks move towards smaller diffraction angles with increasing BHF exposure. This lends support to the idea that hydrogen has been incorporated, as it expands the crystal lattice and increases the out-of-plane lattice constant. Comparison of high angular resolution plots of the (002) plane for 5 specimens before and after 10 to 150 min BHF exposure clearly shows that the diffraction angle θ becomes smaller and that the shift increases with exposure time, as seen in FIG. 15.

Graph 1500 of FIG. 15 shows XRD diagrams of (002) plane (a) before and (b) after 10-150 min BOE exposure. This experiment was carried out on 5 individual wafers. To conclusively demonstrate that hydrogen is injected into the Ta film during BHF exposure, degassing is performed on a blanket film submersed in BHF for 2 h. Another specimen without BHF exposure is also analyzed. H₂ desorption from the acid-treated specimen begins at 400° C., reaches a maximum at 500° C. and becomes negligible at 570° C., as indicated by the black line in FIG. 6. The BHF-treated specimen is reheated to check whether there residual H₂ remains.

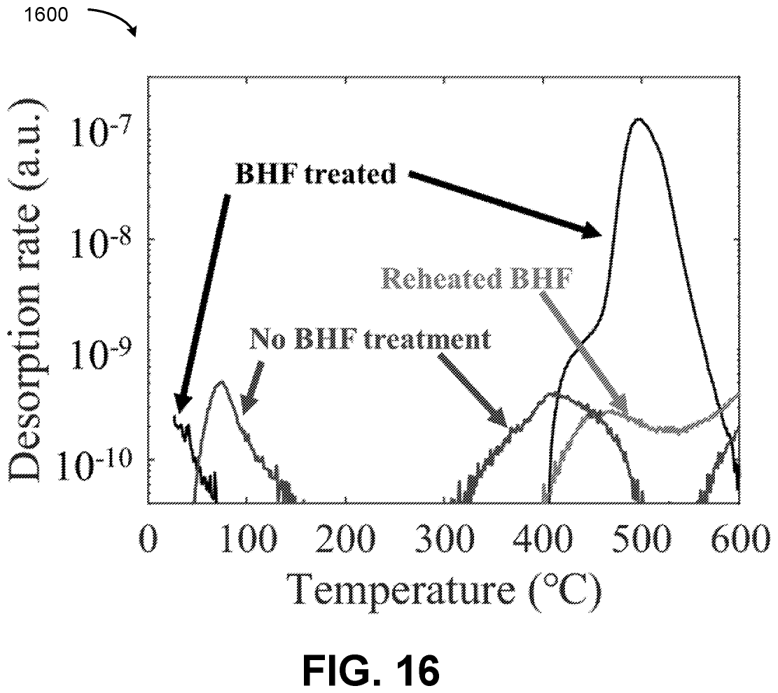

The minimal amount of H₂ desorption reveals that little further H₂ desorbed during the second thermal cycle, as shown in graph 1600 of FIG. 16. The rate of H₂ degassing for the specimen not exposed to BHF at 400° C. is 300 times less than the maximum rate for the specimen exposed to BHF, which occurs at 500° C. The integrated amount over the temperature range from 27° C. to 600° C. of H₂ degassing from the specimen without BHF treatment is 1.4% of the amount from the BHF-treated specimen. Graph 1600 confirms that the compressive residual stress arises from hydrogen absorption during BHF treatment. This also explains why BHF influences the stress of fixed-fixed beams more than that of blanket films. Namely, while hydrogen atoms can diffuse into blanket films only through the top surface, they can diffuse into fixed-fixed beams through the bottom surface as well as through their side walls. Therefore, fixed-fixed beams develop a higher compressive stress than blanket films for a given amount of time, while longer BHF exposure enlarges this difference. This is seen by comparing the stress changes of β-Ta fixed-fixed beams (see graph 1300, line a) to blanket films (line b of graph 1300) as a function of BHF exposure time. The slope of the former is almost twice that of the latter, as quantified in rows (a) and (b) of Table 1. This also indicates that fixed-fixed beams absorb approximately twice as much as hydrogen as blanket films.

TABLE 1
Curve Fitting Of FIG. 13 Stress Change
As a Function Of BHF Exposure Time

| | |
|---|---|
| (a) Blanket β-Ta film | Δσ_{R} = −3.64t + 51.16 |
| (b) β-Ta fixed-fixed beam | Δσ_{R} = −7.35t + 130.00 |
| (c) α-Ta fixed-fixed beam | Δσ_{R} = −13.07t + 398.40 |

The shift to compressive stress in Ta when using a PECVD SiO₂ sacrificial layer and a BHF release results from hydrogen injection by the acid.

α-Ta films are used to show that the hydrogen effect is largely reversible. Thus far, the description describes β-Ta films. If the film deforms only elastically during hydrogen absorption, the residual stress should be recovered after degassing. However, a confounding factor is that the metastable β-Ta transforms to the stable α-phase with a BCC unit cell starting at temperatures as low as 300° C. This transformation completely relaxes the intrinsic compressive stress and eventually results in a tensile stress. The increase in tensile stress can be due to film densification due to differences in the β- and α-phase densities and to grain growth. The XRD diagram of β-Ta films after annealing at 500° C. for 20 min, confirms that the β-Ta partially transforms to the α phase, as seen in FIG. 14 line (c). As shown in FIG. 16, hydrogen desorption begins just above 400° C. and peaks at 500° C., so the phase transition makes it impossible to independently isolate the effect of hydrogen degassing on residual stress.

Although sputter-deposited Ta films usually assume the tetragonal β-phase, they can nucleate and grow in the α-phase on certain seed layers. A 10-nm thick Cr seed layer is used to produce α-Ta. The unit cell of as-deposited α-Ta seeded by Cr is confirmed by XRD, as shown in graph 1400 of FIG. 14, line (d). The stress change induced by the phase transition can be avoided. To stabilize the microstructure and avoid any stress evolution due to thermal treatment during degassing, the blanket α-Ta film is next annealed at 600° C. for 30 min. The biaxial residual stress is −358 MPa after anneal. A residual stress near 0 MPa is achievable in principle by adjusting the sputter pressure, but stress optimization has not yet been conducted.

Following a similar process flow to that described in relation to FIG. 11, fixed-fixed beams made from α-Ta are fabricated and released in BHF for 40 min, 60 min and 75 min (a longer exposure than 75 min to BHF leads to beam delamination of α-Ta). The stress change, Δσ_{R}^{u}, after release of α-Ta beams is determined from the effective uniaxial stress in the blanket film. It is higher than that of β-Ta, as plotted by line (c) in graph 1300 of FIG. 13. The more closely packed crystal structure of α-Ta is more sensitive to hydrogen incorporation. The curve fitting for α-Ta fixed-fixed beams is also shown in Table 1. Degassing is performed at 500° C. for 20 min, and Δσ_{R}^{b} is also plotted as indicated by the purple points in FIG. 13, line (c) of graph 1300. The final change in stress is below −60 MPa after degassing, indicating that the residual stress is largely recovered, as indicated by the vertical dashed arrows in graph 1300.

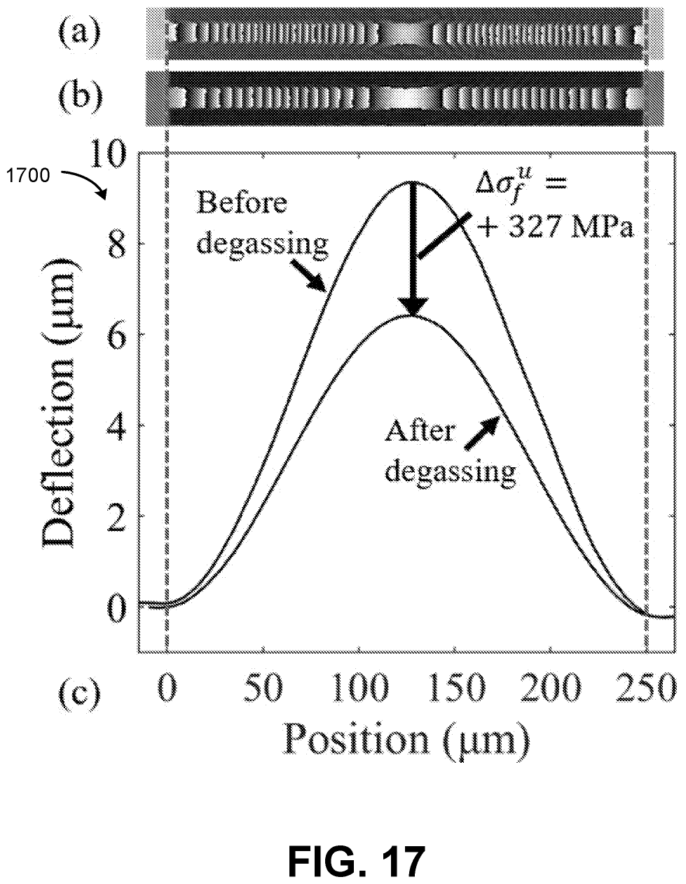

Above 375° C., interstitial oxygen from a Ta₂O₅ surface layer diffuses into Ta. Native Ta₂O₅ increases the compressive stress upon annealing at 375° C. To show the direct effect of hydrogen degassing on α-Ta fixed-fixed beam deflections, representative interferograms were taken. Comparison of a buckled beam after 1 h BHF release and after hydrogen desorption indicates fewer fringes and a lower buckle amplitude after degassing, corresponding to a relaxation of compressive stress to a level nearly commensurate with the as-deposited blanket wafer. This is seen by comparing interferograms (a) and (b) of FIG. 17, and the associated beam deflection curves are seen in graph 1700. At 500° C., the degassing temperature is relatively low compared to 1000° C. which is typically used to anneal stress in polycrystalline silicon MEMS. With careful attention to initial deposition stress of α-Ta films and subsequent degassing under high vacuum, it should be possible to achieve low residual stress Ta films. The results may apply to other metals that are exposed to BHF.

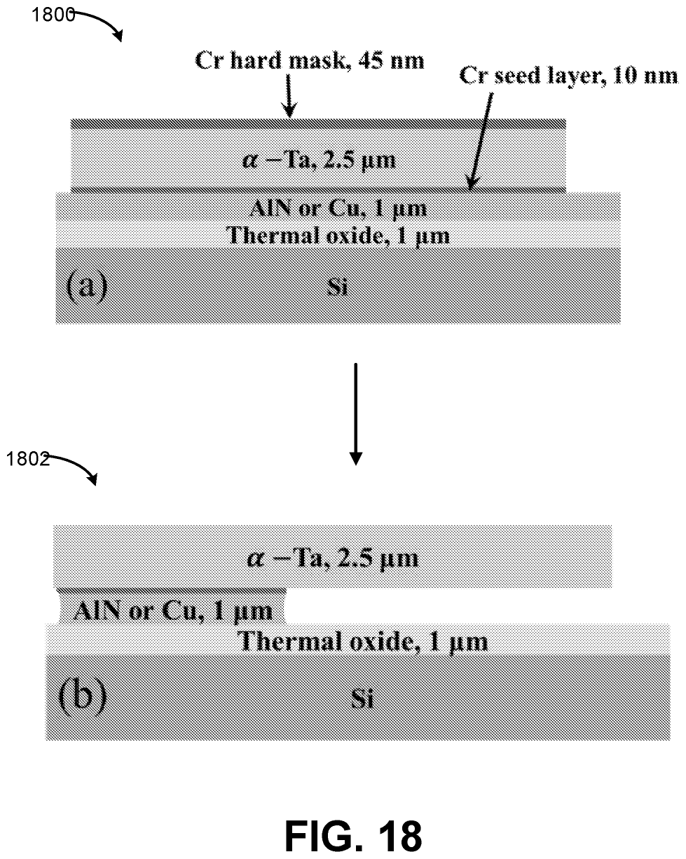

Turning to FIG. 18, sacrificial materials and release etchants for metal MEMS that reduce or eliminate hydrogen-induced residual stress change are now described. As previously described, after Ta deposition, sputter deposition of a 45 nm thick Cr follows, which serves as the hard mask for Ta reactive ion etching (RIE). The Cr mask is patterned using photolithography and ion milling. Then, Ta is anisotropically etched by RIE. The film stack at this point is represented in view 1800 of FIG. 18. Next, the Cr hard mask is removed by a selective Cr etchant, followed by removal of the sacrificial layer. Sacrificial AlN is etched by AZ 400K developer, in which the active chemical species is KOH at room temperature or 85-90° C. Sacrificial Cu is etched by 30 wt. % FeCl3 solution at room temperature. No stirring is applied during etch. Finally, the Ta structures are rendered free-standing by CPD. A simple resulting cantilever structure is schematically represented by structure 1802 of FIG. 18.

Once released, co-fabricated fixed-fixed beams under sufficiently high compression buckle to partially relieve their residual stress. The critical uniaxial buckling stress is

$${σ}_{c}^{u} = \frac{{π}^{2}}{3} {{E}_{f} ( \frac{{h}_{f}}{L} )}^{2} \qquad ( 12 )$$

where L is the length of the beam and E_{f} is the film's Young's modulus. Buckled beams relieve stress and their amplitude A can be used to determine the uniaxial residual stress σ_{b}^{u} present before buckling according to

$${σ}_{b}^{u} = - \frac{{π}^{2} {E}_{f}}{{L}^{2}} ( \frac{{A}^{2}}{4} + \frac{{h}_{f}^{2}}{3} ) \qquad ( 13 )$$

Fixed-fixed beams with lengths of L=500, 750 and 1000 μm are used for stress extraction. Using Eq. (12), the critical buckling stress stresses, σ_{c}^{u}, are calculated to be −15.5 MPa, −6.9 MPa, and −3.9 MPa, respectively for the above beam lengths. In this work, the equivalent uniaxial residual stresses of as-deposited Ta films on AlN and Cu sacrificial layers are −53.0 MPa and −36.6 MPa, respectively. Using Eq. (12), their critical buckling lengths are L_{cr}≈270 μm and L_{cr}≈319 μm, respectively. Eq. (13) is accurate as long as beams have lengths greater than 1.1L_{cr}. Therefore, all the beams are expected to provide accurate results as long as the processing does not induce significant tension due to, for example, growth stresses.

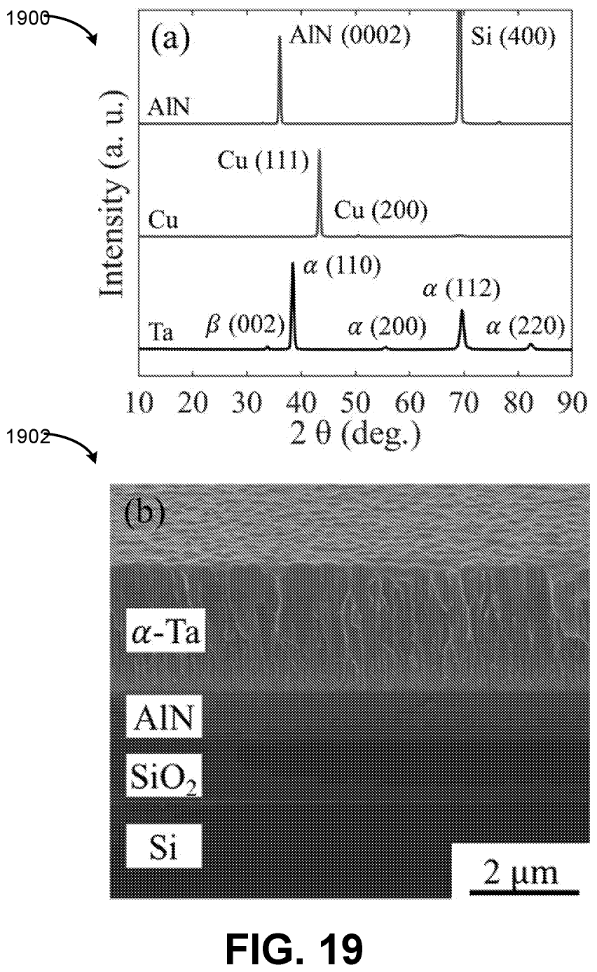

The XRD diagrams of AlN, Cu and Ta thin films are shown in graph 1900 of FIG. 19. The AlN film is strongly (0002) textured (c-axis oriented) with a full width at half maximum (FWHM) of 0.38°. These films provide the highest piezoelectric effect as the hexagonal wurtzite AlN has a spontaneous polarization along the c-axis. The Cu sacrificial layer also has a strong texture with a preferential orientation of (111) planes. The FWHM is approximately 0.41°.

As mentioned above, Ta thin films are most commonly deposited in the metastable tetragonal β-phase with an electrical resistivity of ρₑ≈200 μΩ·cm. However, with the 10-nm-thick Cr seed layer, α-Ta is the predominant phase. A resistivity of ρₑ=21.4 μΩ·cm is measured, which is within the expected range of pure α-Ta (15-60 μΩ·cm). A minimal amount of β-phase is also formed, with one weak peak corresponding to the (002) plane identified at 2θ of 33.8°. With respect to the present study, the β-phase may change the Young's modulus of Ta films, which influences stress extraction via Eq. (12). Nanoindentation tests performed on 2.5 μm thick α- and β-Ta films give a Young's modulus of 188±6.0 GPa and 181±1.3 GPa, respectively, which are close to that of bulk Ta, 185 GPa. The effect of the minimal amount of β-Ta is negligible.

Image 1902 of FIG. 19 shows the film stack of α-Ta deposited on an AlN sacrificial layer. Images of α-Ta deposited on Cu are indistinguishable from 1902 and thus not shown here. Isotropic etching is usually preferred for a sacrificial material to allow for time-efficient removal under the structural material. If the etch is anisotropic, particularly for a strongly textured sacrificial layer, it may proceed slowly or even stop on certain crystal planes, making structure release time-consuming or unsuccessful. Although the Cu sacrificial layer has a strong orientation, no orientation-dependent etch of Cu by FeCl₃ occurs. The 20 μm wide fixed-fixed beams can be released within 90 s at room temperature, indicating a lateral etch rate of 111 nm/s. There is also no indication of Ta chemical etch or attack by the FeCl₃ solution.

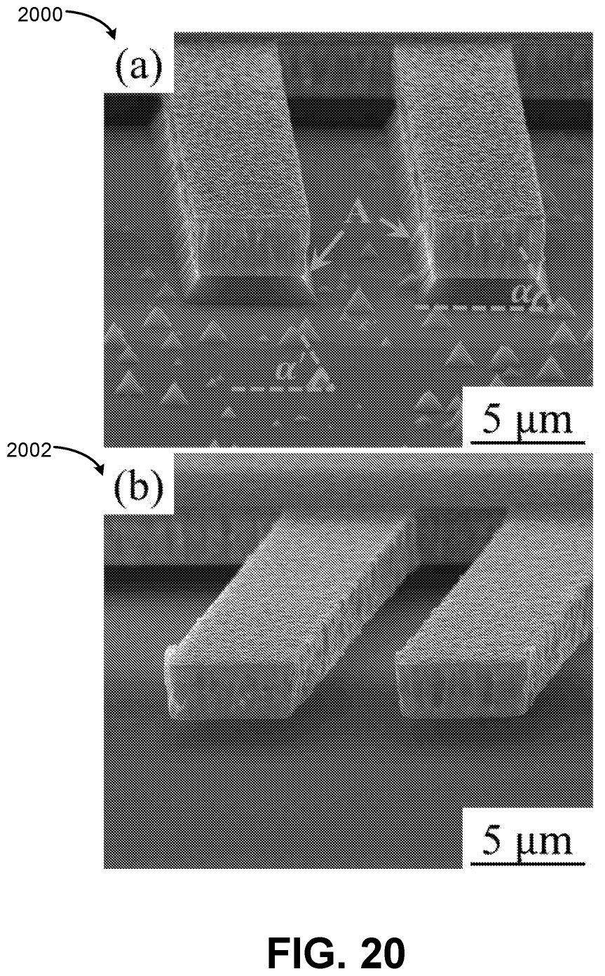

In contrast, etching of the textured AlN is strongly anisotropic and a much lower etch rate by AZ 400K developer at room temperature is observed. After a 30-min etch, the AlN masked by Ta survives and has a trapezoid-shaped cross section, shown in image 2000 of FIG. 20. The surfaces are likely bounded by {101̅1̅} planes, denoted by A, which are chemically stable because of a smaller number of bonds on these planes compared to other plane families. The angle between these planes and the basal plane, as indicated by α, is measured to be 60.4±0.9°. This is in good agreement with the angle between {0001} and {101̅1̅} planes, 61.6°, in crystalline wurtzite AlN.

There are cone-shaped etch residue features in other locations not masked by Ta. These columnar inversion domains nucleate at the film/substrate interface and grow throughout the film thickness with an in-plane dimension of about 40 nm. Since their etch rate is much slower compared to other areas with N-polarity located at the cone center, they are believed to act as micro-masks.

To improve release etch isotropy, the AZ 400K developer is heated from room temperature (RT, 20° C.) to different temperatures ranging 30 to 90° C. It is found that temperatures above 60° C. are sufficiently high to significantly enhance isotropic etching. An example of fully released Ta cantilever beams after a 30-min etch at 85-90° C. is shown in image 2002 of FIG. 20. The etch is isotropic and no etch residue is found. Also, no Ta etching is observed, suggesting that Ta is compatible with the etchant at raised temperatures. The surface roughness of the Ta film is 18 nm root mean square as determined by atomic force microscopy (AFM).

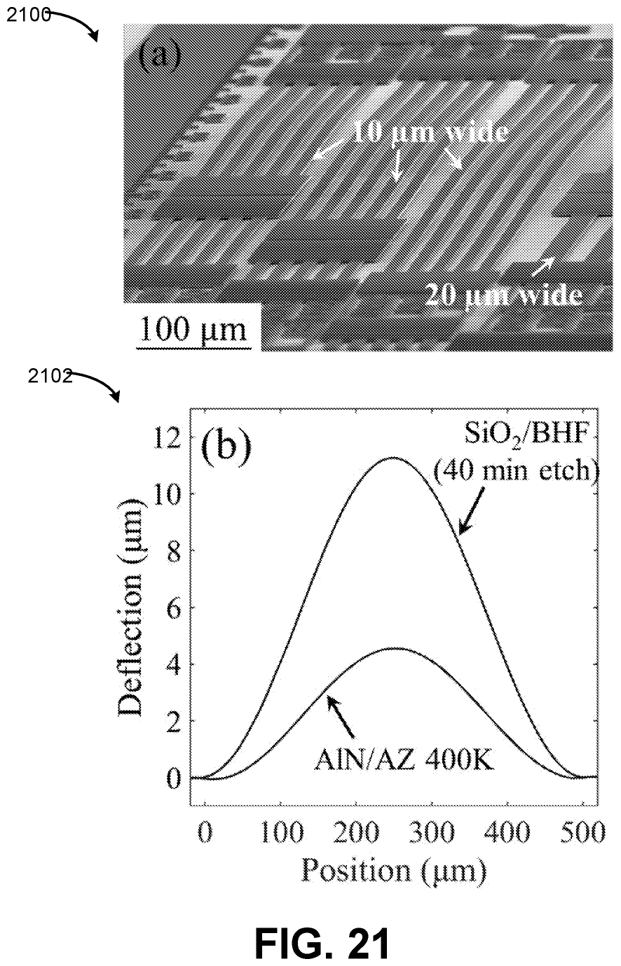

FIG. 21 shows, in image 2100, arrays of 10 μm and 20 μm wide fixed-fixed Ta beams fabricated with sacrificial AlN and successfully released in AZ 400K developer. Graph 2102 shows profiles of beams released in AZ 400K and of 10 μm wide beams fabricated with sacrificial SiO₂ and released in BHF. The amplitude of the beams released in AlN/AZ 400K can be explained by the as-deposited stress of −53 MPa. That is, the stress is unchanged by the release etch.

The film stress after release is extracted using buckled fixed-fixed beams of various lengths. Beam arrays fabricated with sacrificial AlN after a 30-min AZ 400K developer release etch are shown in image 2100 of FIG. 21. The beam widths are 10 or 20 μm: the buckle amplitude is not sensitive to beam width. An example of the deflection profile of a 500-μm long beam is plotted in graph 2102 of FIG. 21, annotated as “AlN/AZ 400K”. By measuring its buckle amplitude, the uniaxial stress is calculated from Eq. (4) to be −53.7 MPa. This is equivalent to the uniaxial residual stress of as-deposited Ta films extracted by wafer curvature measurement, −53.0 MPa, indicating that the AZ 400K developer does not change residual stress and that the release etch is hydrogen free.

For two reasons, the release etch temperature of 85-90° C. has a negligible annealing effect on the film stress. First, for the refractory metal Ta (Tₘ=3017° C.), the release etch temperature is very low. Upon heating and cooling from RT to 150° C., the stress change of blanket Ta films on silicon substrate is linear and reversible. There is no obvious change in grain size or hardness after annealing at temperatures up to 800° C. Therefore, the 85-90° C. anneal has minimal effect on the microstructure and stress of Ta films. Second, H₂ degassing from BHF-treated Ta films begins at 400° C., below which the H₂ desorption rate is minimal. Therefore, if hydrogen was injected into Ta films, the release etch temperature of 85-90° C. would not be sufficiently high to remove hydrogen, thus having no effect on the following stress measurement.

Also plotted in graph 2102 is the deflection profile of a beam right after a 40-min release by removing a SiO₂ sacrificial layer using BHF. The uniaxial stress change after BHF release is −251 MPa and can be attributed to hydrogen absorption. Both the 10 μm and 20 μm wide beams are released after the 30-min AZ 400K developer release etch, but only the 10 μm wide beams are released after the 40-min BHF release etch. Since stress change due to hydrogen incorporation is proportional to BHF exposure time, the increase in compressive stress would be even higher if a longer BHF release were performed. However, after a 75-min BHF etch, yet before the 20 μm wide beams are released, extensive film delamination is seen in areas covering the substrate. The mechanism is possibly compressive stress build-up resulting in extensive telephone cord buckling and subsequent delamination. Such hydrogen-induced buckling was seen.

Additionally, if AlN is used for the sacrificial layer, exposure to silicon should be avoided or reduced during release etch as the AZ 400K developer, or in fact KOH as the active species, etches silicon. This reaction generates hydrogen which may be then absorbed by metals. Cu does not have this issue as FeCl₃ does not react with silicon.

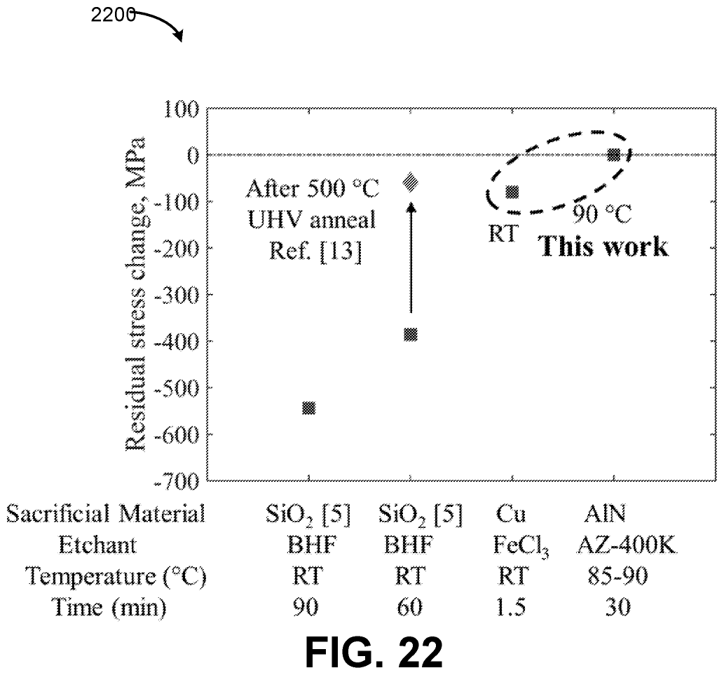

The etch conditions and uniaxial stresses before and after release etch for AlN and Cu sacrificial layers are summarized in Table 2. The results are also graphically represented in graph 2200 of FIG. 22. Ta films experience a high stress change of −386 MPa after 60-min BHF release etch due to hydrogen injection. If annealed in high vacuum at 500° C., as indicated by the diamond in FIG. 22, the stress changes reduces to −59 MPa. However, the 20 μm wide beams are not released at 60 min. Assuming they can be released in 90 min (10 μm wide beams can be released in 40 min), the extrapolated stress change is even higher at about −542 MPa. A much-reduced change in the compressive stress of 80 MPa is measured for the Cu sacrificial layer, where the processing is at RT. AlN provides the best results as the residual stress is unchanged after release at 85 to 90° C., indicating that AlN etching by AZ-400K is hydrogen free.

TABLE 2
Etch conditions and uniaxial stress of as-deposited and
released α-Ta films using AlN/Cu/SiO₂ sacrificial layers

| Sacrificial layer | SiO₂ [13] | SiO₂ [13] | Cu | AlN |
|---|---|---|---|---|
| Etchant | BHF | BHF | FeCl₃ | AZ 400K |
| Temperature (° C.) | RT | RT | RT | 85-90 |
| Time (min) | 90 | 60 | 1.5 | 30 |
| Uniaxial stress (MPa, as-deposited) | −236.3 | −236.3 | −36.6 | −53.0 |
| Uniaxial stress (MPa, released) | −777.9 (extrapolated) | −622.5 ± 49.0 | −116.9 ± 13.9 | −52.9 ± 9.7 |
| Uniaxial stress change (MPa) | −543.6 | −386.2 | −80.3 | +0.1 |

AlN sacrificial material and AZ 400K etch is compatible with many other metals that can survive KOH etch. These include Cu, Pt, Au, Mo, W, Ni, Pd and Ag, but not Al which is rapidly etched by KOH. A long AZ 400K release etch may be an issue for those metals slowly etched in KOH, including V, Nb, Ta and Cr, though no noticeable Ta etch is observed.

AlN release is hydrogen free, so there is no stress change incurred when using the AlN release process. A maximum temperature of the metallization process is 90° C., so the AlN release process is compatible with making MEMS after CMOS fabrication. Generally, CMOS structures can tolerate a max temperature of 500° C. and preferably below 400° C., while the AlN release process is performed at temperatures between 60-90° C.

Anisotropic Reactive Ion Etching of Thick α-Ta Films is now described. Vertical walls for 2.5 μm thick α-Ta films are formed by reactive ion etching (RIE), which is important for surface micromachining applications such as thermal actuators and accelerometers and gyroscopes. Etch variables, including gas composition and flow, pressure and power, and a loading effect, are qualitatively investigated. α-Ta etch anisotropy has a similar dependence on etch variables as does Si, but shows different characteristics from SiO₂. Using a common parallel-plate RIE configuration and CF₄ gas as the reactive species, a vertical sidewall across an entire 4″ wafer is achieved. A vertical sidewall is consistently obtained with anisotropic etching of α-Ta.

The substrates used are 4″ thermally oxidized (100) Si wafers. Ta films are sputtered onto the substrate to a nominal thickness of h_{f}=2.5 μm in a load-locked DC magnetron sputtering system at a base pressure lower than 7×10⁻⁸ Torr without intentional heating or biasing. The working gas is pure Ar. Before deposition, the substrate is sputter cleaned at a power of 250 W for 1 min. At the same power of 250 W, the deposition rate is approximately 19 nm/min. To nucleate α-Ta, a 10 nm thick Cr seed layer is deposited at a power of 100 W and deposition rate of 11 nm/min, followed by Ta deposition in the same sputter machine without breaking vacuum. Crystal structures of as-deposited Ta films are determined using X-ray diffraction (XRD), with a copper anode operated at 45 kV and 40 milliamps (mA). Scanning is performed with a maximum range of 10° to 90°. Resistivity is measured using a standard four-point probe configuration.

After Ta deposition, sputter deposition of a 45 nm thick Cr follows, which serves as the hard mask for Ta etch. The Cr mask is patterned using photolithography and ion milling. Due to the high selectivity, the Cr mask can be very thin, which minimizes pattern transfer error.

The etching is performed in a conventional parallel-plate RIE chamber (Trion Phantom II RIE system equipped with a turbo vacuum pump). The chuck, or bottom electrode, upon which the samples rest, produces a negative DC bias which increases ion bombardment and anisotropy while etching. The RF power is generated at 13.56 MHz. The gases are mixed and supplied into the chamber volume at the top center. The gas flow rates are controlled by mass flow controllers (MFCs). The reactive gas species is CF4, while 02 and Ar can be added. Changeable etch parameters include the RF power, gas flow rate and chamber pressure.

While bulk Ta always assumes the α-phase, Ta thin films are most commonly deposited in the metastable tetragonal β-phase. Ta directly deposited onto thermally grown oxide indicates a tetragonal unit cell, indicated by the relatively high electrical resistivity of ρₑ=173 μΩ·cm. To produce α-Ta, appropriate seed layers must be used. The candidates may include W, Mo, TaN, and Cr. Ta films deposited onto a 10-nm-thick Cr seed layer assumes the predominant α-phase with a resistivity of ρₑ=21.4 μΩ·cm, which is close to the lower bound of pure α-Ta resistivity (15-60 μΩ·cm).

To investigate effects of etch parameters, arrays of 1 μm wide beams are imaged in SEM after each etch under different etch conditions. The etch is performed on a 15×15 mm chip. The initial etch recipe gas flows are 6 sccm CF4, 1 sccm 02 and 30 sccm Ar at a chamber pressure of 100 mTorr and power of 44 W. However, with this etch recipe, severe undercut is observed and the 1 μm wide beams do not survive before the etch is finished. An array of 2 μm wide features after this etch is shown in FIG. 23a. The cross section has a trapezoidal shape as the material close to film surface is exposed to etch chemicals for a longer duration. It should be noted that the film is not etched through to completion.

If over etched, lateral etch becomes more severe due to longer exposure to chemicals, as shown in images 2300 and 2302 in FIG. 23. For this reason, before the film is fully etched through, etches are aborted and then test chips are imaged to compare the influence of etch parameters without additional undercut due to over etch. To improve anisotropy, an effort is first made to vary the flow rate of O₂, a gas that is typically used to enhance etch rate. The cross-section profile at an O₂ flow rate of 3 sccm is shown in image 2304. However, undercut is not reduced and 1 μm features still cannot survive the etch. By contrast, by removing O₂ from the etch chemicals, a significant improvement in sidewall protection is observed. The 1 μm feature after etch is shown in image 2306, though lateral etch still exists. Sidewall profiles at various O₂ flow rates include 1 sccm for image 2300, 1 sccm (over etched) for image 2302, 3 sccm for image 2304 and 0 sccm for image 2306. Other etch parameters are CF₄ flow of 6 sccm, Ar flow of 30 sccm, pressure of 100 mTorr and power of 44 W.

Fluorine is the active species and readily etches Ta. O2 can bond with C to release more F from the CF4 gas, but this leads to more chemical etch in the lateral direction. Meanwhile, a reduction of C reduces carbon-fluorine (CFx) formation on the reaction surface, which serves as a passivation layer to prevent further sidewall etch. A similar phenomenon is also observed in silicon etch, where O2 is usually added to increase F-to-C ratio and reduce polymerization. Because of this, O2 is removed from the etch gases in the following experiments.

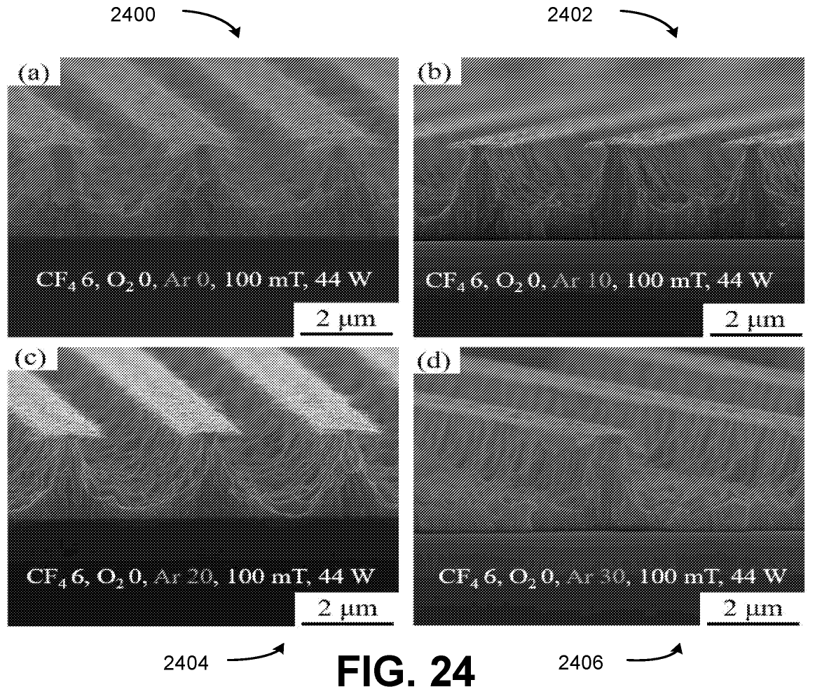

The Ar flow rate is varied from zero to 30 sccm, while maintaining a CF4 flow rate of 6 sccm, pressure of 100 mTorr and power of 44 W. The results are shown in FIG. 24. Compared with the etch using CF₄ only (image 2400), the addition of Ar tends to improve the etch anisotropy, and a significantly improvement is seen when the Ar flow rate is increased to 30 sccm of image 2406. Sidewall profiles at various Ar flow rates of 0 sccm at image 2400, 10 sccm for image 2402, 20 sccm for image 2404, and 30 sccm for image 2406. Other etch parameters are CF4 flow of 6 sccm, O2 flow of 0 sccm, pressure of 100 mTorr and power of 44 W.

Unlike He, Ar has a tendency to be ionized upon plasma ignition. The energetic ions, driven by the bias voltage during etch, are highly directional and typically only strike the bottom of an opening. This ion bombardment helps to remove any non-volatile by-products or etch inhibitors such as CFx polymer on the bottom, and therefore enhances directional etch. An Ar flow rate of 30 sccm is used for the following etches.

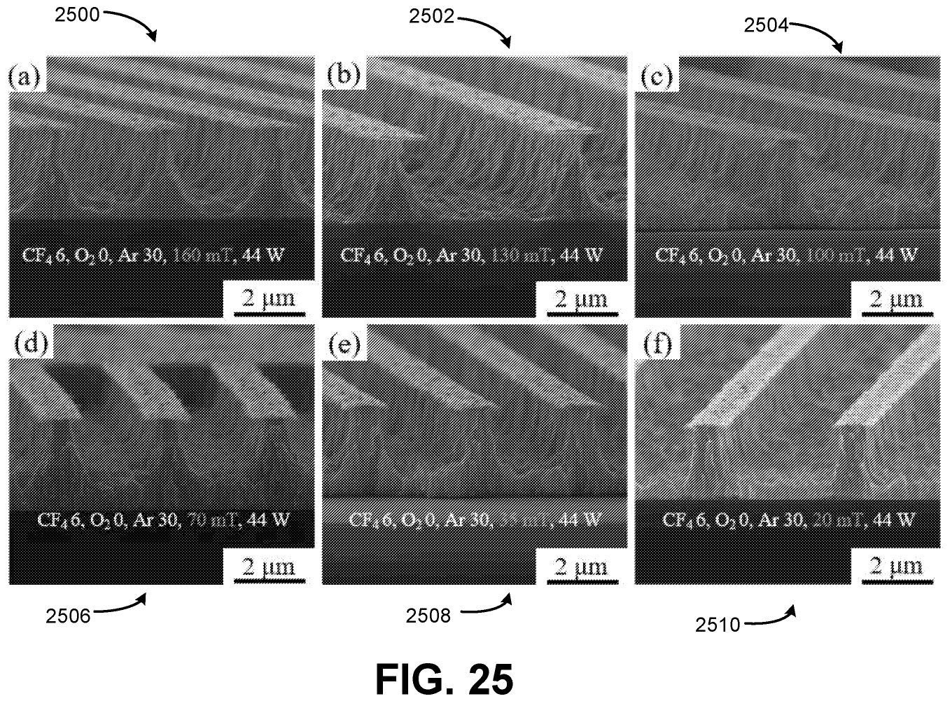

At a CF4 flow rate of 6 sccm, an Ar flow rate of 30 sccm and a power of 44 W, the pressure is varied from 160 to 20 mTorr. Results are shown in images 2500, 2502, 2504, 2506, 2508, and 2510 of FIG. 25. Unless gas flows are reduced, the lowest achievable pressure is about 20 mTorr with the current etch tool. A clear trend can be seen that as the pressure goes down, lateral etch is gradually reduced. A similar phenomenon was also observed for tungsten films RIE'd by fluorine-based chemicals. This is because under same process conditions, the bias voltage increases as pressure decreases.

Therefore, a lower pressure raises ion energy and enhances ion bombardment, which has an equivalent effect to a higher Ar flow. For CF4 gas, an increase in bias voltage of approximately 200 V was measured when the chamber pressure was reduced from 250 to 100 mTorr. In addition, more gas molecules are supplied to the process chamber at higher pressures, and a larger fluorine atom concentration results. A linear relationship was actinometrically measured between fluorine atom concentration, ranging from 2×1014 to 5×10¹⁴ atoms/cm³, and pressure, ranging from 100 to 500 mTorr. As a result, chemical etch in the lateral direction is enhanced. A similar dependence of sidewall protection on pressure was also observed for chlorine chemically-etched Ta. However, the pressure did not continue to drop as photoresist was used as the mask in that work and a lower pressure reduced the selectivity between Ta and photoresist. Unlike photoresist, Cr is very resistant to the etch chemistries used in this work and therefore the etch process optimization is not limited by the selectivity of Ta and the mask material. FIG. 25 shows sidewall profiles at various pressures of (a) 160 mTorr, (b) 130 mTorr, (c) 100 mTorr, (d) 70 mTorr, (e) 35 mTorr and (f) 20 mTorr. Other etch parameters are CF4 flow of 6 sccm, O2 flow of 0 sccm, Ar flow rate of 30 sccm and power of 44 W.

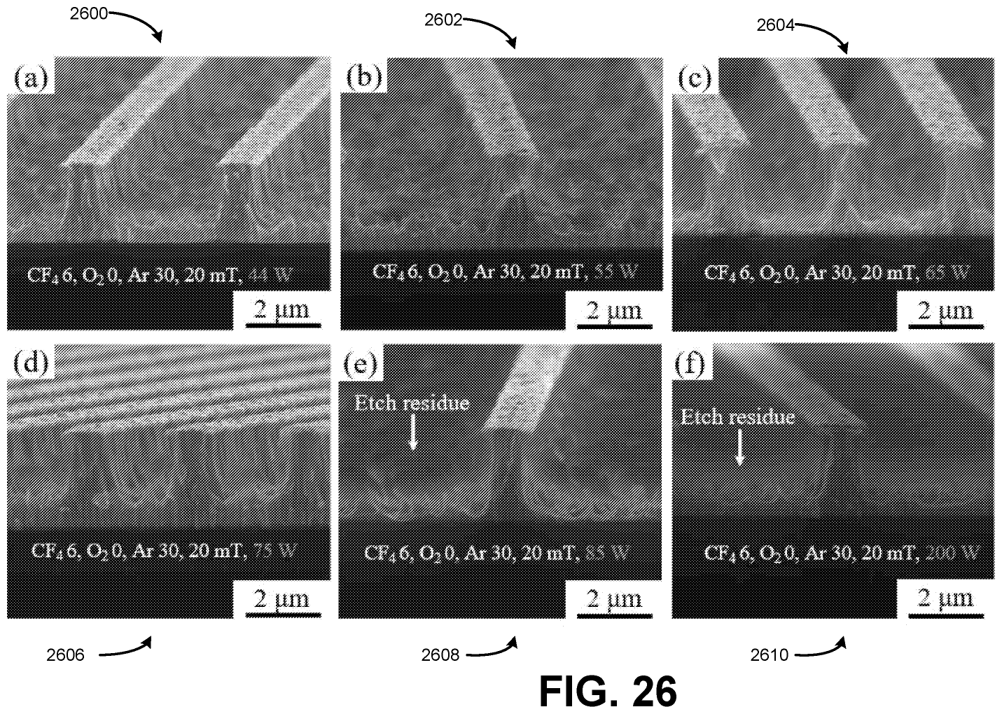

Because pressure cannot be lowered at the current gas flows, the RF power is increased instead. An increased power raises the bias voltage and enhances kinetic ion bombardment, which is expected to have a similar effect to a lower pressure. The etch profiles at a gradually increased powers from 44 W to 200 W are shown in images 2600, 2602, 2604, 2606, 2608, and 2610 of FIG. 26 However, there is not a clear trend between lateral etch and RF power. Even more etch residue at 85 W and 200 W with a height comparable to the film thickness is observed. This is likely because of enhanced preferential etch along grain boundaries at higher powers, leaving the columnar grain interior behind, though the exact mechanism is not yet clear. The lack of improved sidewall profile with increased power may be explained by an already saturated ion bombardment effect at a low chamber pressure of 20 mTorr. In other words, energetic ion induced by-product, reaction inhibitor removal and ion-enhanced etch at the bottom of an opening is already maximized. Therefore, the vertical sidewall profile cannot be obtained simply through minimization of chamber pressure and maximization of RF power. Sidewall profiles at various powers of (a) 44 W, (b) 55 W, (c) 65 W, (d) 75 W, (e) 85 W and (f) 200 W. Other etch parameters are CF4 flow of 6 sccm, O2 flow of 0 sccm, Ar flow rate of 30 sccm and pressure of 20 mTorr.

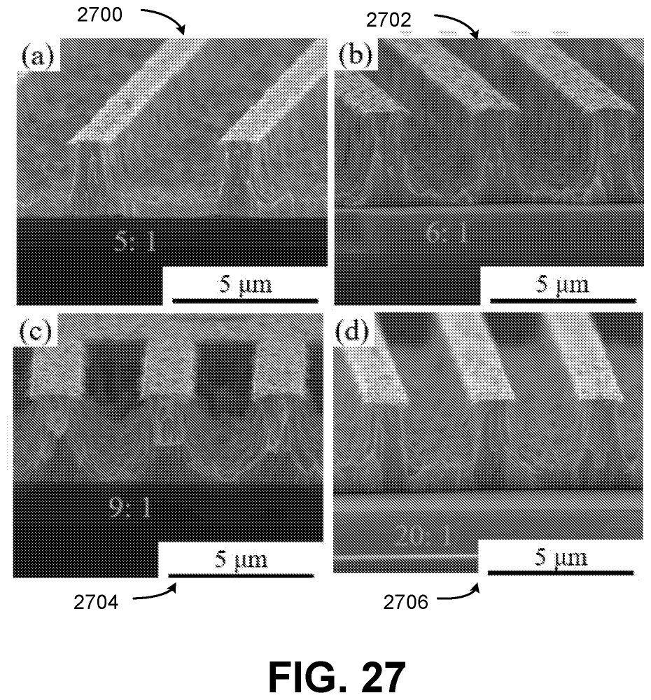

To validate the saturation effect of the ion bombardment, the Ar to CF4 gas flow ratio is further increased. As the Ar:CF4 flow ratio reaches a maximum of 5:1, the increased Ar flow has a clear effect on sidewall protection. However, as shown in FIG. 27, as the Ar:CF4 flow ratio (image 2700) is increased to 6:1 (image 2702), 9:1 (images 2704) and 20:1 (image 2706), an improved sidewall profile is not observed. This provides further evidence that enhanced ion bombardment plays a minimal role in further reduction of lateral etch.

The above observation that vertical sidewalls cannot be obtained simply by maximizing ion bombardment indicates a similarity between Ta and Si etch mechanisms. It is known that much care should be taken to obtain an anisotropic Si etch—it requires an optimal etch condition, otherwise extensive undercut may result. For Si etches using fluorine, the reaction product formation and desorption are both spontaneous at room temperature. If either is not spontaneous but requires the assistance of energetic ions, no undercut is observed as the ions are highly directional and only impact the bottom of an opening. As a result, although ion bombardment is saturated, randomly moving F radicals, which are the neutral species and do not respond to bias voltage, can still spontaneously react with material on the sidewalls, leading to some extent of lateral etch even if at a lower rate than the ion-assisted vertical etch. To eliminate lateral etch, a passivation layer, typically a CFx polymer, is needed to stop the etch on sidewalls. The Bosch process is one example. Ta can be etched by XeF₂ gas without intentional heating or glow discharge. By contrast, SiO₂, another common material in semiconductor industry, does not react with F radicals spontaneously without the activation energy provided by energetic ions. Therefore, anisotropic etch using F-based chemicals is more easily obtained for SiO₂.

The above experiments are all performed on a single chip (15×15 mm). Much improved sidewall profile, though not optimal, is obtained under etch conditions of CF4 flow of 6 sccm, Ar flow of 30 sccm, pressure of 20 mTorr and RF power of 44 W. Compared with ion milling, an important difference is that in RIE reactive gas species are consumed. The consumption increases as a larger quantity of material to be etched is present in the system. Such a loading effect is observed for Si etch with a decreased etch rate as more materials are loaded.

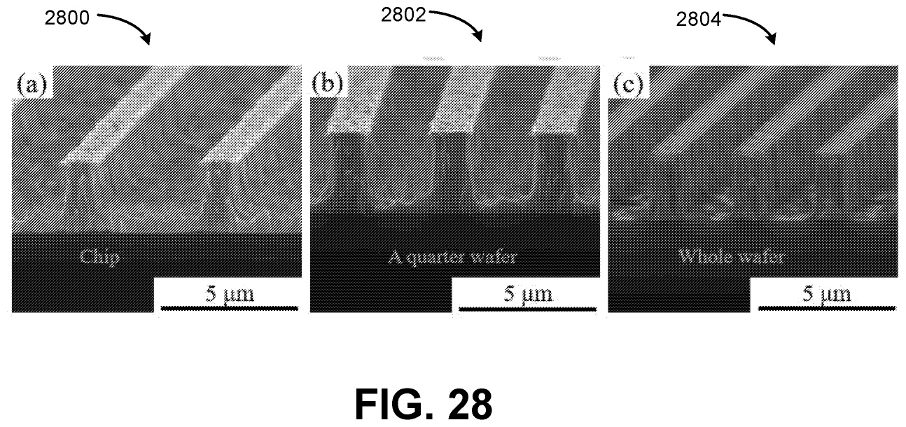

To investigate instead the loading effect on sidewall profile, a quarter wafer, containing 6 chips, and a whole wafer, containing 24 chips, are etched under the same etch conditions as a single chip. Compared with a single chip, shown in image 2800 of FIG. 28, lateral etch is significantly reduced for a quarter wafer (image 2802), and vertical sidewall is finally obtained for a whole wafer at an etch rate of approximately 35 nm/min, as shown in image 2804.

The eliminated lateral etch arises from polymer deposition on the sidewall for relatively large area samples. Additional consumption of fluorine when more Ta material is exposed leads to a deficiency in fluorine and thus unsaturated fluorocarbons. Their existence results in presence of increased polymerization on the sidewall which inhibits lateral etch. Again, similar to Si, the loading effect of Ta is a result of a net loss of F due to the lesser formation of volatile TaF5 (SiF4 for Si). This effect is much less significant for SiO2 because the oxygen released from SiO2 combines with carbon and frees more F, which compensates for the F consumption due to SiF4 formation.

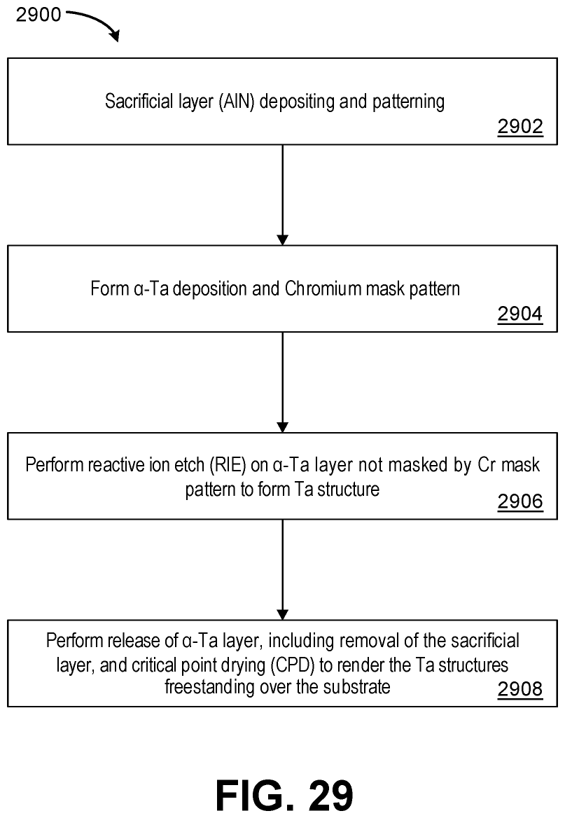

FIG. 29 shows an example process 2900 for forming Ta-based MEMS in accordance with the processes described herein. At step 2902, an AlN sacrificial layer depositing and patterning is performed. At step (2904), an α-Ta deposition and Chromium 205 mask pattern are formed. At step (2906), an α-Ta reactive ion etch (RIE) is performed to etch portions of the α-Ta layer, as subsequently described. At step (2908), a release (removal of the sacrificial layer) and critical point drying (CPD) are performed to render the Ta structures freestanding over the substrate (including CMOS transistors).

While this specification includes many specific implementation details, these should not be construed as limitations on the scope of what may be claimed, but rather as descriptions of features that may be specific to particular implementations. Certain features that are described in this specification in the context of separate implementations can also be implemented, in combination, in a single implementation. Conversely, various features that are described in the context of a single implementation can also be implemented in multiple implementations, separately, or in any suitable sub-combination. Moreover, although previously described features may be described as acting in certain combinations and even initially claimed as such, one or more features from a claimed combination can, in some cases, be excised from the combination, and the claimed combination may be directed to a sub-combination or variation of a sub-combination.

Particular implementations of the subject matter have been described. Other implementations, alterations, and permutations of the described implementations are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations may be considered optional), to achieve desirable results.

Moreover, the separation or integration of various system modules and components in the previously described implementations should not be understood as requiring such separation or integration in all implementations, and it should be understood that the described program components and systems can generally be integrated together in a single software product or packaged into multiple software products.

Accordingly, the previously described example implementations do not define or constrain the present disclosure. Other changes, substitutions, and alterations are also possible without departing from the spirit and scope of the present disclosure.

What is claimed is:

1. A micro-electromechanical system (MEMS) device, comprising:
a silicon substrate; and
a Tantalum layer comprising a first portion and a second portion, a first portion being suspended over the silicon substrate and configured to move relative to the silicon substrate, and the second portion of the structure being coupled to the silicon substrate and fixed in place relative to the silicon substrate.

2. The MEMS device of claim 1, wherein the silicon substrate forms a portion of an integrated circuit (IC), wherein the Tantalum layer and the IC are included in a package.

3. The MEMS device of claim 1, further comprising:
a sacrificial layer between the silicon substrate and the Tantalum layer, wherein a first portion of the sacrificial layer is etched away to release the first portion from the silicon substrate, and wherein a second portion of the sacrificial layer remains and couples the silicon substrate to the Tantalum layer.

4. The MEMS device of claim 3, wherein the sacrificial layer comprises Aluminum Nitride (AlN), Copper (Cu), or Silicon Oxide (SiO₂).

5. The MEMS device of claim 1, wherein the first portion comprises etched Tantalum, and wherein a sidewall profile of the etched Tantalum comprises approximately zero lateral etch or an etch angle between 85-90° C.

6. The MEMS device of claim 1, the first portion comprising:
a plurality of legs extending from a first side of the silicon substrate or a second side of the silicon substrate to connect at a shuttle, the plurality of legs being coupled to the silicon substrate at the first and second sides, wherein the plurality of legs support in-plane movement of the shuttle.

7. The MEMS device of claim 6, wherein at least one leg of the plurality of legs are each between 1-2.5 micrometers (μms) thick, and wherein each of the plurality of legs have an approximately equal thickness.

8. The MEMS device of claim 6, wherein each of the plurality of legs have an approximately equal width.

9. The MEMS device of claim 6, wherein at least one leg of the plurality of legs has a width of approximately 1 μm and spaced about 2-4 μm.

10. The MEMS device of claim 1, wherein the first portion has a residual stress of less than 50 megaPascals (MPa), the residual stress being based on a buffered hydrofluoric acid (BHF) release of the first portion from a sacrificial layer.

11. The MEMS device of claim 1, wherein the first portion comprises a central portion suspended over the silicon substrate and configured to move up to 5 μm responsive to an electrical or thermal input.

12. The MEMS device of claim 1, wherein the Tantalum layer is formed directly on a CMOS circuit, and wherein an isotropic release etching of the sacrificial layer comprising AlN is between 60° C.-90° C.

13. The MEMS device of claim 1, wherein the Tantalum layer comprises grain sizes of approximately 160 nm.

14. The MEMS device of claim 1, wherein the Tantalum layer is at least 2.5 micrometers (μm) thick.

15. The MEMS device of claim 1, wherein the Tantalum layer comprises α-Tantalum.

16. The MEMS device of claim 1, wherein the first portion of the Ta layer forms a portion of a thermal actuator (TA).

17. The MEMS device of claim 16, wherein the first portion is configured to deflect at least 1.5 um in response to receiving a current of less than 15 mA based on a length, a width, or a thickness of the first portion of the Ta layer.

18. The MEMS device of claim 16, wherein the first portion is configured to deflect at approximately 1 μm in response to receiving a temperature of about 100° C. based on a length, a width, or a thickness of the first portion of the Ta layer.

19. The MEMS device of claim 1, further comprising a Chromium seed layer configured to nucleate the Tantalum layer during sputtering.

20. The MEMS device of claim 1, wherein the first portion of the Ta layer forms a cantilever.

21. The MEMS device of claim 1, wherein the first portion of the Ta layer is part of an accelerometer.

22. The MEMS device of claim 1, further comprising a coating such as atomic layer deposition of Al₂O₃ configured to provide oxidation resistance.

23. A micro-electromechanical system (MEMS) actuator device, comprising:
a silicon substrate; and
a α-Tantalum film forming a plurality of leg pairs, the leg pairs extending from a first side of the α-Tantalum film or a second side of the Tantalum film to a shuttle suspended above the silicon substrate, the first and second sides being affixed to the silicon substrate by at least one underlayer, the plurality of leg pairs being configured for in-plane deflection relative to the silicon substrate.

24. The MEMS actuator device of claim 23, wherein each leg of the plurality of leg pairs is at least 150 μm long, 2.5 μm thick, and 1 μm wide.

25. The MEMS actuator device of claim 23, wherein each leg of the plurality of leg pairs comprises a sidewall profile having approximately no lateral etch.

26. The MEMS actuator device of claim 23, wherein the underlayer comprises a thermal SiO₂ sacrificial layer, a Chromium hard mask, or both.

27. The MEMS actuator device of claim 23, wherein each leg of the plurality of leg pairs is configured for a 5 μm offset of the central shuttle in a deactivated position and up to a 10 μm offset of the central shuttle in an activated position.

28. A micro-electromechanical system (MEMS) device, comprising:
an oxide substrate;
a Tantalum structure coupled to a first portion of the oxide substrate, a portion of the Tantalum structure extending over a second portion of the oxide and configured to move relative to the oxide substrate; and
a complementary metal-oxide-semiconductor (CMOS) structure formed in the oxide substrate, the CMOS structure being electrically coupled to the Ta structure.

29. The MEMS device of claim 28, wherein the Tantalum structure forms a comb.

30. The MEMS device of claim 28, wherein the Tantalum structure forms one of a cantilever, a fixed-fixed beam, or other structure fixed on two ends.
